(19) United States
(12) Patent Application Publication
(10) Pub. No.: US 2014/0339550 A1
(43) Pub. Date: Nov. 20, 2014

(54) LAMINATED STRUCTURE, FERROELECTRIC GATE THIN FILM TRANSISTOR, AND FERROELECTRIC THIN FILM CAPACITOR

(71) Applicant: JAPAN SCIENCE AND TECHNOLOGY AGENCY, Kawaguchi-shi, Saitama (JP)

(72) Inventors: Tatsuya Shimoda, Nomi-shi (JP); Takaaki Miyasako, Yokkaichi-shi (JP); Eisuke Tokumitsu, Minato-ku (JP); Bui Nguyen Quoc Trinh, Thanh Xuan (VN)

(21) Appl. No.: 14/359,262

(22) PCT Filed: Oct. 23, 2012
(86) PCT No.: PCT/JP2012/077326

§ 371 Date: May 19, 2014

(30) Foreign Application Priority Data
Nov. 18, 2011 (JP) 2011-252182

(51) Int. Cl. H01L 29/51; H01L 29/49; H01L 29/24; H01L 21/02

(52) U.S. Cl. CPC H01L 29/516; H01L 21/02192; H01L 29/4908; H01L 29/24
USPC 257/43; 257/295; 257/532; 428/701

(57) ABSTRACT

Provided is a ferroelectric gate thin film transistor which includes: a channel layer; a gate electrode layer which controls a conductive state of the channel layer; and a gate insulation layer which is arranged between the channel layer and the gate electrode layer and is formed of a ferroelectric layer. The gate insulation layer (ferroelectric layer) has the structure where a PZT layer and a BLT layer (Pb diffusion preventing layer) are laminated to each other. The channel layer (oxide conductor layer) is arranged on a surface of the gate insulation layer (ferroelectric layer) on a BLT layer (Pb diffusion preventing layer) side. The ferroelectric gate thin film transistor can overcome various drawbacks which may be caused due to the diffusion of Pb atoms into an oxide conductor layer from a PZT layer including a drawback that a transmission characteristic of a ferroelectric gate thin film transistor is liable to be deteriorated (for example, a width of a memory window is liable to become narrow).

### RELATED APPLICATIONS

The present application is a National Phase of International Application Number PCT/JP2012/077326 filed Oct. 23, 2012 and claims priority to Japanese Application Number 2011-252182 filed Nov. 18, 2011.

### TECHNICAL FIELD

The present invention relates to a laminated structure, a ferroelectric gate thin film transistor and a ferroelectric thin film capacitor.

### BACKGROUND ART

FIG. 18 is a view for explaining a conventional ferroelectric gate thin film transistor 900.

As shown in FIG. 18, the conventional ferroelectric gate thin film transistor 900 includes: a source electrode 950 and a drain electrode 960; a channel layer 940 which is positioned between the source electrode 950 and the drain electrode 960; a gate electrode 920 which controls a conduction state of the channel layer 940; and a gate insulation layer 930 which is formed between the gate electrode 920 and the channel layer 940 and is made of a ferroelectric material. In FIG. 18, symbol 910 indicates an insulating substrate.

In the conventional ferroelectric gate thin film transistor 900, a ferroelectric material (for example, BLT (Bi₄₋ₓLaₓTi₃O₁₂) or PZT (Pb(Zrₓ, Ti₁₋ₓ)O₃)) is used as a material for forming the gate insulation layer 930, and an oxide conductive material (for example, indium tin oxide (ITO)) is used as a material for forming the channel layer 940.

According to the conventional ferroelectric gate thin film transistor 900, an oxide conductive material is used as a material for forming the channel layer and hence, a carrier concentration in the channel layer can be increased. Further, a ferroelectric material is used as a material for forming the gate insulation layer and hence, switching of the ferroelectric gate thin film transistor 900 can be performed at a low drive voltage at a high speed. As a result, it is possible to control a large electric current at a low drive voltage at a high speed. Further, the ferroelectric gate thin film transistor 900 has a hysteresis characteristic and hence, the transistor can be suitably used as a memory element or a battery element.

The conventional ferroelectric gate thin film transistor can be manufactured by a method of manufacturing a conventional ferroelectric gate thin film transistor shown in FIG. 19A to FIG. 19F. FIG. 19 A to FIG. 19F are views for explaining the method of manufacturing the conventional ferroelectric gate thin film transistor. FIG. 19A to FIG. 19E are views showing respective steps of the method, and FIG. 19F is a plan view of the ferroelectric gate thin film transistor 900.

Firstly, as shown in FIG. 19A, on an insulating substrate 910 formed of an Si substrate on a surface of which an SiO₂ layer is formed, a gate electrode 920 formed of a laminated film made of Ti (10 nm) and Pt (40 nm) is formed by an electron beam vapor deposition method.

Next, as shown in FIG. 19B, a gate insulation layer 930 (200 nm) made of BLT (B_{3.25}La_{0.75}Ti₃O₁₂) or PZT (Pb(Zr_{0.4}Ti_{0.6})O₃) is formed by sol-gel method from above the gate electrode 920.

Next, as shown in FIG. 19C, a channel layer 940 (5 nm to 15 nm) made of ITO is formed on the gate insulation layer 930 by an RF sputtering method.

Next, as shown in FIG. 19D, a source electrode 950 and a drain electrode 960 are formed on the channel layer 940 by depositing Ti (30 nm) and Pt (30 nm) in vacuum on the channel layer 940 by an electron beam vapor deposition method.

Next, an element region is separated from another element region by an RIE method and a wet etching method (HF: HCl mixed liquid).

In this manner, the ferroelectric gate thin film transistor 900 shown in FIG. 19E and FIG. 19F can be manufactured.

FIG. 20 is a view for explaining a transmission characteristic of the conventional ferroelectric gate thin film transistor 900. In FIG. 20, symbol 940a indicates a channel, and symbol 940b indicates a depletion layer.

In the conventional ferroelectric gate thin film transistor 900, as shown in FIG. 20, when the gate voltage is 3V (VG=3V), approximately 10⁻⁴ A is obtained as an ON current, 1×10⁴ is obtained as an ON/OFF ratio, 10 cm²/Vs is obtained as an field effect mobility μ_{FE}, and a value of approximately 2V is obtained as a memory window.

### PRIOR ART LITERATURE

### Patent Literature

### [Patent Literature 1] JP-2006-121029

### SUMMARY OF INVENTION

### Technical Problem

To realize the manufacture of the excellent ferroelectric gate thin film transistor 900 described above using considerably smaller amounts of raw materials and a considerably smaller amount of manufacturing energy compared to the conventional manufacturing method and, at the same time, using shorter steps compared to the conventional manufacturing method, inventors according to the present invention have arrived at an idea of manufacturing at least a portion of layers which constitute the above-mentioned ferroelectric gate thin film transistor using a liquid process, and have made extensive studies on the idea.

In the process of the studies, the inventors according to the present invention have found out a drawback that when a PZT layer manufactured using a liquid process is used as a gate insulation layer, and an oxide conductor layer (for example, ITO layer) manufactured using a liquid process is used as a channel layer, a transmission characteristic of a ferroelectric gate thin film transistor is liable to be deteriorated (for example, a width of a memory window is liable to become narrow). The inventors according to the present invention have also found out that a cause of the drawback that a transmission characteristic of the ferroelectric gate thin film transistor is liable to be deteriorated (for example, a width of a memory window is liable to become narrow) lies in that Pb atoms diffuse into the oxide conductor layer from the PZT layer.

It is also found out from the studies made by the inventors according to the present invention, such a phenomenon is not a phenomenon which occurs only with respect to a ferroelectric gate thin film transistor but is a phenomenon which occurs over all “laminated structures where a PZT layer and an oxide conductive layer are laminated to each other” including a ferroelectric thin film capacitor. It is also found out from the studies made by the inventors according to the present invention that such a phenomenon is not a phenomenon which occurs only with respect to “laminated structures where a PZT layer manufacture using a liquid process and an oxide conductor layer manufactured using a liquid process are laminated to each other”, but is a phenomenon which similarly occurs also when at least one of a PZT layer and an oxide conductor layer is manufactured using a gas phase method.

The present invention has been made in view of the above-mentioned circumstances, and it is an object according to the present invention to provide a laminated structure, a ferroelectric gate thin film transistor and a ferroelectric thin film capacitor which can overcome various drawbacks which may be caused due to the diffusion of Pb atoms into an oxide conductor layer from a PZT layer including a drawback that a transmission characteristic of a ferroelectric gate thin film transistor is liable to be deteriorated (for example, a width of a memory window is liable to become narrow).

### Means for Overcoming Drawbacks

The inventors according to the present invention have made extensive studies on the prevention of diffusion of Pb atoms into an oxide conductor layer from a PZT layer. As a result of the studies, the inventors according to the present invention have found out that the above-mentioned object can be achieved by interposing a characteristic layer formed of a BLT layer, an LaTaOx layer, an LaZrOx layer or an SrTaOx layer as a Pb diffusion preventing layer between a PZT layer and an oxide conductor layer, and have completed the present invention.

[1] According to one aspect according to the present invention, there is provided a laminated structure which includes: a ferroelectric layer having the structure where a PZT layer and a Pb diffusion preventing layer formed of a BLT layer, an LaTaOx layer, an LaZrOx layer or an SrTaOx layer are laminated to each other; and an oxide conductor layer which is arranged on a surface of the ferroelectric layer on a Pb diffusion preventing layer side.

According to the laminated structure according to the present invention, the Pb diffusion preventing layer formed of the BLT layer, the LaTaOx layer, the LaZrOx layer or the SrTaOx layer surely exists between the PZT layer and the oxide conductor layer and hence, diffusion of Pb atoms into the oxide conductor layer from the PZT layer can be prevented whereby various drawbacks which may be caused due to the diffusion of Pb atoms into the oxide conductor layer from the PZT layer can be overcome.

In the present invention, the ferroelectric layer means a layer which exhibits ferroelectric characteristic over the entire ferroelectric layer. Accordingly, the concept of the ferroelectric layer includes not only a ferroelectric layer having the structure where a PZT layer exhibiting a ferroelectric characteristic and a BLT layer exhibiting a ferroelectric characteristic are laminated to each other but also a ferroelectric layer having the structure where a PZT layer exhibiting ferroelectric characteristic and an LaTaOx layer, an LaZrOx layer or an SrTaOx layer exhibiting paraelectric characteristic are laminated to each other.

[2] In the laminated structure according to the present invention, it is preferable that the oxide conductor layer is formed of an ITO layer, an In—O layer or an IGZO layer.

The ITO layer, the In—O layer or the IGZO layer has a property that Pb atoms are liable to be diffused. However, according to the laminated structure according to the present invention, the Pb diffusion preventing layer formed of a BLT layer, an LaTaOx layer, an LaZrOx layer or an SrTaOx layer surely exists between the PZT layer and the oxide conductor layer. Accordingly, even in such a case, it is possible to overcome various drawbacks which may be caused due to the diffusion of the Pb atoms into the oxide conductor layer from the PZT layer.

[3] In the laminated structure according to the present invention, it is preferable that a thickness of the Pb diffusion preventing layer falls within a range of 10 nm to 30 nm.

The reason that it is preferable to set the thickness of the Pb diffusion preventing layer to a value which falls within a range from 10 nm to 30 nm is as follows. That is, when the thickness of the Pb diffusion preventing layer is less than 10 nm, there may be a case where an amount of Pb which arrives at the oxide conductor layer from the PZT layer becomes an amount which cannot be ignored. On the other hand, when the thickness of the Pb diffusion preventing layer exceeds 30 nm, the use of the BLT layer as the Pb diffusion preventing layer may increase a leak current of a ferroelectric gate thin film transistor due to a relatively large average particle size of particles which constitute the BLT layer. On the other hand, the use of an LaTaOx layer, an LaZrOx layer or an SrTaOx layer as the Pb diffusion preventing layer may lower a ferroelectric characteristic of the ferroelectric layer since the LaTaOx layer, the LaZrOx layer or the SrTaOx layer is formed of a paraelectric material.

[4] In the laminated structure according to the present invention, the PZT layer may be manufactured using a liquid process.

The PZT layer manufactured using a liquid process has a property that Pb atoms are liable to be released in the manufacturing process. However, according to the laminated structure according to the present invention, the Pb diffusion preventing layer formed of a BLT layer, an LaTaOx layer, an LaZrOx layer or an SrTaOx layer surely exists between the PZT layer and the oxide conductor layer. Accordingly, even in such a case, it is possible to overcome various drawbacks which may be caused due to the diffusion of the Pb atoms into the oxide conductor layer from the PZT layer. Further, by manufacturing the PZT layer using a liquid process, it is possible to provide the laminated structure which can be manufactured using considerably smaller amounts of raw materials and a considerably smaller amount of manufacturing energy compared to the conventional manufacturing methods and, at the same time, using shorter steps compared to the conventional manufacturing methods.

[5] In the laminated structure according to the present invention, the oxide conductor layer may be manufactured using a liquid process.

An oxide conductor layer manufactured using a liquid process has a property that Pb atoms are more liable to be diffused compared to an oxide conductor layer manufactured using a gas phase method. However, according to the laminated structure according to the present invention, the Pb diffusion preventing layer formed of a BLT layer, an LaTaOx layer, an LaZrOx layer or an SrTaOx layer surely exists between the PZT layer and the oxide conductor layer. Accordingly, even in such a case, it is possible to overcome various drawbacks which may be caused due to the diffusion of the Pb atoms into the oxide conductor layer from the PZT layer. Further, by manufacturing the oxide conductor layer using a liquid process, it is possible to provide the laminated structure which can be manufactured using considerably smaller amounts of raw materials and a considerably smaller amount of manufacturing energy compared to the conventional manufacturing methods and, at the same time, using shorter steps compared to the conventional manufacturing methods.

[6] In the laminated structure according to the present invention, the Pb diffusion preventing layer may be manufactured using a liquid process.

In this manner, by manufacturing the Pb diffusion preventing layer using a liquid process, it is possible to provide the laminated structure which can be manufactured using considerably smaller amounts of raw materials and a considerably smaller amount of manufacturing energy compared to the conventional manufacturing methods and, at the same time, using shorter steps compared to the conventional manufacturing methods.

[7] According to another aspect according to the present invention, there is provided a ferroelectric gate thin film transistor which includes: a channel layer; a gate electrode layer which controls a conductive state of the channel layer; and a gate insulation layer which is arranged between the channel layer and the gate electrode layer and is formed of a ferroelectric layer, wherein the ferroelectric layer has the structure where a PZT layer and a Pb diffusion preventing layer formed of a BLT layer, an LaTaOx layer, an LaZrOx layer or an SrTaOx layer are laminated to each other, at least one of the channel layer and the gate electrode layer is formed of an oxide conductor layer, and the oxide conductor layer is arranged on a surface of the ferroelectric layer on a Pb diffusion preventing layer side.

According to a ferroelectric gate thin film transistor according to the present invention, the Pb diffusion preventing layer formed of the BLT layer, the LaTaOx layer, the LaZrOx layer or the SrTaOx layer surely exists between the PZT layer and the oxide conductor layer and hence, diffusion of Pb atoms into the oxide conductor layer from the PZT layer can be prevented whereby various drawbacks which may be caused due to the diffusion of Pb atoms into the oxide conductor layer from the PZT layer can be overcome including a drawback that a transmission characteristic of the ferroelectric gate thin film transistor is liable to be lowered (for example, a width of a memory window is liable to become narrow).

[8] In the ferroelectric gate thin film transistor according to the present invention, it is preferable that the oxide conductor layer is formed of an ITO layer, an In—O layer or an IGZO layer.

The ITO layer, the In—O layer or the IGZO layer has a property that Pb atoms are liable to be diffused. However, according to the ferroelectric gate thin film transistor according to the present invention, the Pb diffusion preventing layer formed of a BLT layer, an LaTaOx layer, an LaZrOx layer or an SrTaOx layer surely exists between the PZT layer and the oxide conductor layer. Accordingly, even in such a case, it is possible to overcome various drawbacks which may be caused due to the diffusion of the Pb atoms into the oxide conductor layer from the PZT layer.

[9] In the ferroelectric gate thin film transistor according to the present invention, it is preferable that a thickness of the Pb diffusion preventing layer falls within a range of 10 nm to 30 nm.

The reason that it is preferable to set the thickness of the Pb diffusion preventing layer to a value which falls within a range from 10 nm to 30 nm is as follows. That is, when the thickness of the Pb diffusion preventing layer is less than 10 nm, there may be a case where an amount of Pb which arrives at the oxide conductor layer from the PZT layer becomes an amount which cannot be ignored. Further, when the BLT layer is used as the Pb diffusion preventing layer, there may be a case where a transmission characteristic of the ferroelectric gate thin film transistor is deteriorated (for example, a width of a memory window is liable to become narrow). On the other hand, when the thickness of the Pb diffusion preventing layer exceeds 30 nm, the use of the BLT layer as the Pb diffusion preventing layer may increase a leak current of a ferroelectric gate thin film transistor due to a relatively large average particle size of particles which constitute the BLT layer, and may deteriorate a transmission characteristic of the ferroelectric gate thin film transistor (for example, a width of a memory window is liable to become narrow, an ON current is lowered, or an OFF current is increased). On the other hand, the use of an LaTaOx layer, an LaZrOx layer or an SrTaOx layer as the Pb diffusion preventing layer may lower a ferroelectric characteristic of the ferroelectric layer since the LaTaOx layer, the LaZrOx layer or the SrTaOx layer is formed of a paraelectric material.

When a BLT layer is used as the Pb diffusion preventing layer, it is preferable that a thickness of the Pb diffusion preventing layer falls within a range of 10 nm to 20 nm.

When the thickness of the Pb diffusion preventing layer exceeds 20 nm, as can be also understood from examples described later, there may be a case where a transmission characteristic of the ferroelectric gate thin film transistor is slightly deteriorated (a width of a memory window becomes slightly narrow).

[10] In the ferroelectric gate thin film transistor according to the present invention, the PZT layer may be manufactured using a liquid process.

The PZT layer manufactured using a liquid process has a property that Pb atoms are liable to be released in the manufacturing process. However, according to the ferroelectric gate thin film transistor according to the present invention, the Pb diffusion preventing layer formed of a BLT layer, an LaTaOx layer, an LaZrOx layer or an SrTaOx layer surely exists between the PZT layer and the oxide conductor layer. Accordingly, even in such a case, it is possible to overcome various drawbacks which may be caused due to the diffusion of the Pb atoms into the oxide conductor layer from the PZT layer. Further, by manufacturing the PZT layer using a liquid process, it is possible to provide the ferroelectric gate thin film transistor which can be manufactured using considerably smaller amounts of raw materials and a considerably smaller amount of manufacturing energy compared to the conventional manufacturing methods and, at the same time, using shorter steps compared to the conventional manufacturing methods.

[11] In the ferroelectric gate thin film transistor according to the present invention, the oxide conductor layer may be manufactured using a liquid process.

An oxide conductor layer manufactured using a liquid process has a property that Pb atoms are more liable to be diffused compared to an oxide conductor layer manufactured using a gas phase method. However, according to the ferroelectric gate thin film transistor according to the present invention, the Pb diffusion preventing layer formed of a BLT layer, an LaTaOx layer, an LaZrOx layer or an SrTaOx layer surely exists between the PZT layer and the oxide conductor layer. Accordingly, even in such a case, it is possible to overcome various drawbacks which may be caused due to the diffusion of the Pb atoms into the oxide conductor layer from the PZT layer. Further, by manufacturing the oxide conductor layer using a liquid process, it is possible to provide the ferroelectric gate thin film transistor which can be manufactured using considerably smaller amounts of raw materials and a considerably smaller amount of manufacturing energy compared to the conventional manufacturing methods and, at the same time, using shorter steps compared to the conventional manufacturing methods.

[12] In the ferroelectric gate thin film transistor according to the present invention, the Pb diffusion preventing layer may be manufactured using a liquid process.

In this manner, by manufacturing the Pb diffusion preventing layer using a liquid process, it is possible to provide the ferroelectric gate thin film transistor which can be manufactured using considerably smaller amounts of raw materials and a considerably smaller amount of manufacturing energy compared to the conventional manufacturing methods and, at the same time, using shorter steps compared to the conventional manufacturing methods.

[13] The ferroelectric gate thin film transistor of present invention, the channel layer may be formed of the oxide conductor layer.

When Pb atoms diffuse into the channel layer, a transmission characteristic of the ferroelectric gate thin film transistor largely deteriorates (for example, a width of a memory window is liable to become extremely narrow). However, according to the ferroelectric gate thin film transistor according to the present invention, the Pb diffusion preventing layer formed of a BLT layer, an LaTaOx layer, an LaZrOx layer or an SrTaOx layer surely exists between the PZT layer and the channel layer (oxide conductor layer). Accordingly, even in such a case, it is possible to overcome various drawbacks which may be caused due to the diffusion of the Pb atoms into the channel layer from the PZT layer.

[14] In the ferroelectric gate thin film transistor according to the present invention, the gate electrode layer may be formed of the oxide conductor layer.

When Pb atoms diffuse into the gate electrode layer, the reliability of the ferroelectric gate thin film transistor is lowered. However, according to the ferroelectric gate thin film transistor according to the present invention, the Pb diffusion preventing layer formed of a BLT layer, an LaTaOx layer, an LaZrOx layer or an SrTaOx layer surely exists between the PZT layer and the gate electrode layer (oxide conductor layer). Accordingly, it is possible to prevent the diffusion of Pb atoms into the gate electrode layer and hence, the reliability of the ferroelectric gate thin film transistor can be enhanced.

In the ferroelectric gate thin film transistor according to the present invention, the transistor may further include a source electrode layer and a drain electrode layer which are arranged on the channel layer in a contact manner.

Further, in the ferroelectric gate thin film transistor according to the present invention, the transistor may further include a source electrode layer and a drain electrode layer which are formed on the same layer as the channel layer.

In this case, in the ferroelectric gate thin film transistor according to the present invention, it is preferable that the transistor has the stepped structure where a layer thickness of the channel layer is set smaller than a layer thickness of the source electrode layer and a layer thickness of the drain electrode layer. It is preferable that such stepped structure is formed using a press molding technique.

[15] According to still another aspect according to the present invention, there is provided a ferroelectric thin film capacitor which includes: a first electrode layer; a second electrode layer, and a dielectric layer which is arranged between the first electrode layer and the second electrode layer and is formed of a ferroelectric layer, wherein the ferroelectric layer has the structure where a PZT layer and a Pb diffusion preventing layer formed of a BLT layer, an LaTaOx layer, an LaZrOx layer or an SrTaOx layer are laminated to each other, at least one of the first electrode layer and the second electrode layer is formed of an oxide conductor layer, and the oxide conductor layer is arranged on a surface of the ferroelectric layer on a Pb diffusion preventing layer side.

According to the ferroelectric thin film capacitor according to the present invention, the Pb diffusion preventing layer formed of the BLT layer, the LaTaOx layer, the LaZrOx layer or the SrTaOx layer surely exists between the PZT layer and the oxide conductor layer and hence, diffusion of Pb atoms into the oxide conductor layer from the PZT layer can be prevented whereby it is possible to overcome a drawback that an electric characteristic of the ferroelectric thin film capacitor is liable to deteriorate (for example, the number of times that the capacitor can be charged and discharged is liable to be decreased).

[16] In the ferroelectric thin film capacitor according to the present invention, it is preferable that the oxide conductor layer is formed of an ITO layer, an In—O layer or an IGZO layer.

The ITO layer, the In—O layer or the IGZO layer has a property that Pb atoms are liable to be diffused. However, according to the ferroelectric thin film capacitor according to the present invention, the Pb diffusion preventing layer formed of a BLT layer, an LaTaOx layer, an LaZrOx layer or an SrTaOx layer surely exists between the PZT layer and the oxide conductor layer. Accordingly, even in such a case, it is possible to overcome various drawbacks which may be caused due to the diffusion of Pb atoms into the oxide conductor layer from the PZT layer.

[17] In the ferroelectric thin film capacitor according to the present invention, it is preferable that a thickness of the Pb diffusion preventing layer falls within a range of 10 nm to 30 nm.

The reason that it is preferable to set the thickness of the Pb diffusion preventing layer to a value which falls within a range from 10 nm to 30 nm is as follows. That is, when the thickness of the Pb diffusion preventing layer is less than 10 nm, there may be a case where an amount of Pb which arrives at the oxide conductor layer from the PZT layer becomes an amount which cannot be ignored. Further, due to such a cause, there may be a case where an electric characteristic of the ferroelectric thin film capacitor is liable to deteriorate (for example, the number of times that the capacitor can be charged and discharged is liable to be decreased). On the other hand, when the thickness of the Pb diffusion preventing layer exceeds 30 nm, the use of the BLT layer as the Pb diffusion preventing layer may increase a leak current of a ferroelectric gate thin film transistor due to a relatively large average particle size of particles which constitute the BLT layer. On the other hand, the use of an LaTaOx layer, an LaZrOx layer or an SrTaOx layer as the Pb diffusion preventing layer may lower a ferroelectric characteristic of the ferroelectric layer since the LaTaOx layer, the LaZrOx layer or the SrTaOx layer is formed of a paraelectric material.

[18] In the ferroelectric thin film capacitor according to the present invention, the PZT layer may be manufactured using a liquid process.

The PZT layer manufactured using a liquid process has a property that Pb atoms are liable to be released in the manufacturing process. However, according to the ferroelectric thin film capacitor according to the present invention, the Pb diffusion preventing layer formed of a BLT layer, an LaTaOx layer, an LaZrOx layer or an SrTaOx layer surely exists between the PZT layer and the oxide conductor layer. Accordingly, even in such a case, it is possible to overcome various drawbacks which may be caused due to the diffusion of the Pb atoms into the oxide conductor layer from the PZT layer. Further, by manufacturing the PZT layer using a liquid process, it is possible to provide the ferroelectric thin film capacitor which can be manufactured using considerably smaller amounts of raw materials and a considerably smaller amount of manufacturing energy compared to the conventional manufacturing methods and, at the same time, using shorter steps compared to the conventional manufacturing methods.

[19] In the ferroelectric thin film capacitor according to the present invention, the oxide conductor layer may be manufactured using a liquid process.

An oxide conductor layer manufactured using a liquid process has a property that Pb atoms are more liable to be diffused compared to an oxide conductor layer manufactured using a gas phase method. However, according to the ferroelectric thin film capacitor according to the present invention, the Pb diffusion preventing layer formed of a BLT layer, an LaTaOx layer, an LaZrOx layer or an SrTaOx layer surely exists between the PZT layer and the oxide conductor layer. Accordingly, even in such a case, it is possible to overcome various drawbacks which may be caused due to the diffusion of the Pb atoms into the oxide conductor layer from the PZT layer. Further, by manufacturing the oxide conductor layer using a liquid process, it is possible to provide the ferroelectric thin film capacitor which can be manufactured using considerably smaller amounts of raw materials and a considerably smaller amount of manufacturing energy compared to the conventional manufacturing methods and, at the same time, using shorter steps compared to the conventional manufacturing methods.

[20] In the ferroelectric thin film capacitor according to the present invention, the Pb diffusion preventing layer may be manufactured using a liquid process.

In this manner, by manufacturing the Pb diffusion preventing layer using a liquid process, it is possible to provide the ferroelectric thin film capacitor which can be manufactured using considerably smaller amounts of raw materials and a considerably smaller amount of manufacturing energy compared to the conventional manufacturing methods and, at the same time, using shorter steps compared to the conventional manufacturing methods.

[21] In the ferroelectric thin film capacitor according to the present invention, the first electrode layer and the second electrode layer may be formed of the oxide conductor layer respectively, and the ferroelectric layer has the structure where a first Pb diffusion preventing layer arranged on the first electrode layer in a contact manner, the PZT layer and a second Pb diffusion preventing layer arranged on the second electrode layer in a contact manner may be laminated to each other.

Due to such constitution, it is possible to provide the ferroelectric thin film capacitor having high symmetry. Further, it is possible to provide the ferroelectric thin film capacitor which can be relatively easily manufactured using a liquid process.

In the present invention, PZT is a ferroelectric material expressed by “Pb (Zrₓ, Ti₁₋ₓ)O₃”, and BLT is a ferroelectric material expressed by “Bi₄₋ₓLaₓTi₃O₁₂”. LaTaOx is a paraelectric material formed of a composite oxide made of La and Ta, LaZrOx is a paraelectric material formed of a composite oxide made of La and Zr, and SrTaOx is a paraelectric material formed of a composite oxide made of Sr and Ta. ITO is an oxide conductor material formed of a composite oxide made of In and Zn, In—O is an oxide conductor material formed of an oxide made of In, IGZO is an oxide conductor material formed of a composite oxide made of In, Ga and Zn.

### BRIEF DESCRIPTION OF DRAWINGS

FIG. 1 is a view for explaining a ferroelectric gate thin film transistor 20 according to an embodiment 1.

FIG. 2A to FIG. 2E are views for explaining a method of manufacturing the ferroelectric gate thin film transistor 20 according to the embodiment 1.

FIG. 3 is a view for explaining a ferroelectric thin film capacitor 30 according to an embodiment 2.

FIG. 4A to FIG. 4D are views for explaining a method of manufacturing the ferroelectric thin film capacitor 30 according to the embodiment 2.

FIG. 5A to FIG. 5C are views for explaining a ferroelectric gate thin film transistor 100 according to an embodiment 3.

FIG. 6A to FIG. 6F are views for explaining a method of manufacturing the ferroelectric gate thin film transistor 100 according to the embodiment 3.

FIG. 7A to FIG. 7F are views for explaining the method of manufacturing ferroelectric gate thin film transistor 100 according to the embodiment 3.

FIG. 8A to FIG. 8E are views for explaining the method of manufacturing the ferroelectric gate thin film transistor 100 according to the embodiment 3.

FIG. 9A to FIG. 9E are views for explaining the method of manufacturing the ferroelectric gate thin film transistor 100 according to the embodiment 3.

FIG. 10A and FIG. 10B are views for explaining ferroelectric gate thin film transistors 20, 90 according to test examples 1, 2.

FIG. 11A and FIG. 11B are photographs for explaining the cross-sectional structure of the ferroelectric gate thin film transistors 20, 90 according to the test examples 1, 2.

FIG. 12A to FIG. 12C are photographs for explaining the cross-sectional structure of the ferroelectric gate thin film transistors 20, 90 according to the test examples 1, 2.

FIG. 13A and FIG. 13B are views showing the Pb distribution in the ferroelectric gate thin film transistors 20, 90 according to the test examples 1, 2.

FIG. 14A and FIG. 14B are views showing a transmission characteristic of the ferroelectric gate thin film transistors 20, 90 according to the test examples 1, 2.

FIG. 15A to FIG. 15F are views showing transmission characteristics of ferroelectric gate thin film transistors 20a to 20f according to test examples 3 to 8.

FIG. 16 is a table showing evaluation results of the ferroelectric gate thin film transistors 20, 90, 20a to 20f according to the test examples 1 to 8.

FIG. 17A to FIG. 17C are graphs showing leak currents in ferroelectric thin film capacitors which uses an LaTaOx layer, an LaZrOx layer and an SrTaOx layer respectively.

FIG. 18 is a view for explaining a conventional thin film transistor 900.

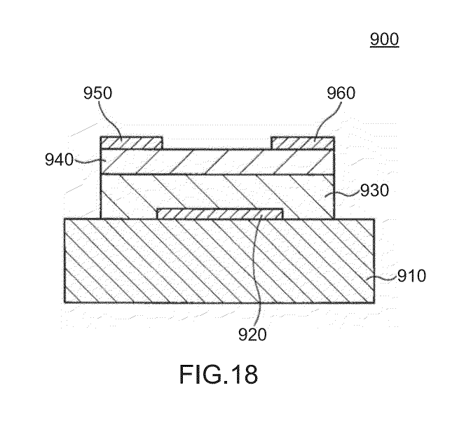

FIG. 19A to FIG. 19F are views for explaining a method of manufacturing the conventional thin film transistor.

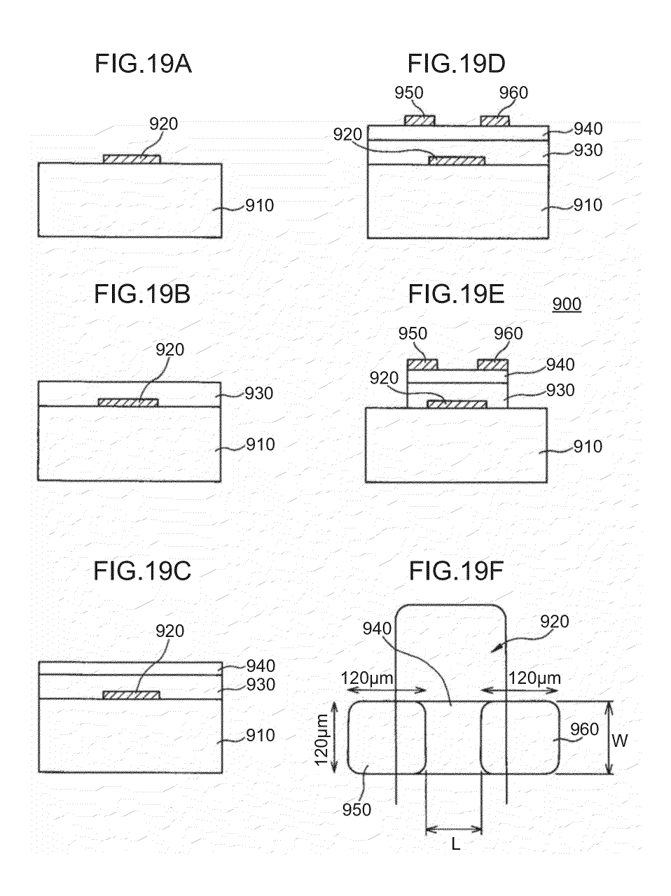

FIG. 20 is a view for explaining an electric characteristic of the conventional thin film transistor 900.

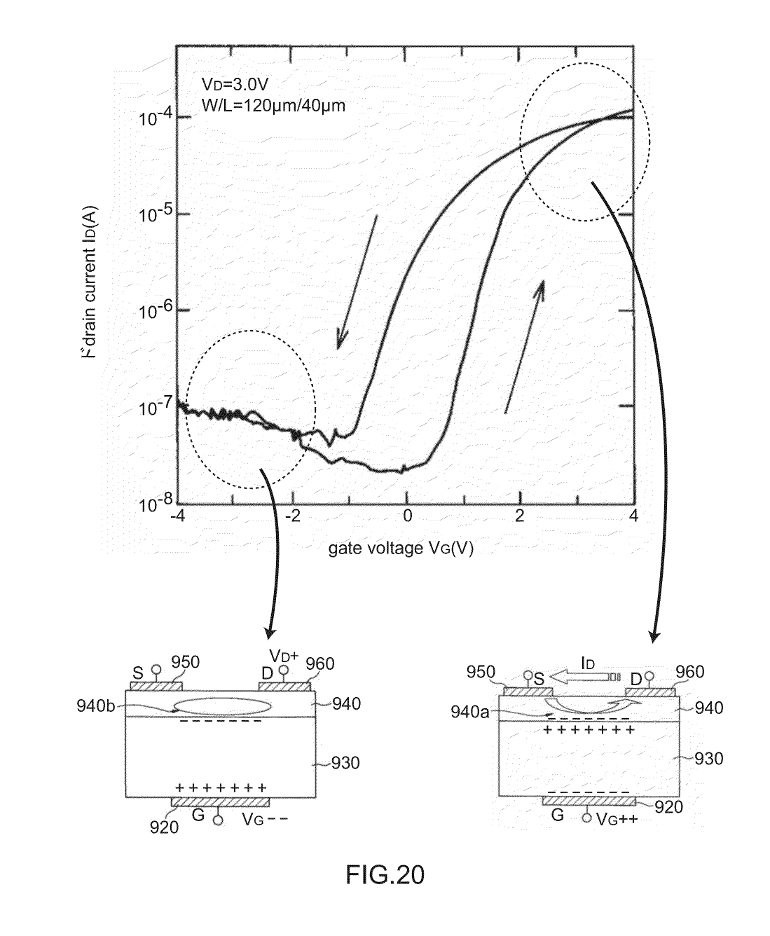

### DESCRIPTION OF EMBODIMENTS

Hereinafter, a laminated structure, a ferroelectric gate thin film transistor and a ferroelectric thin film capacitor according to the present invention are explained by reference to embodiments shown in drawings.

### Embodiment 1

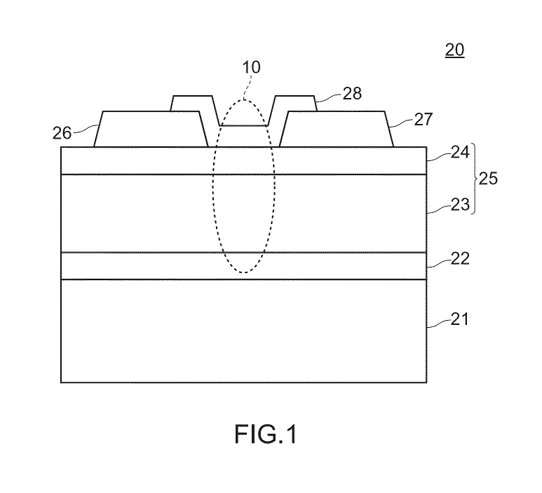

FIG. 1 is a view for explaining a ferroelectric gate thin film transistor 20 according to the embodiment 1.

As shown in FIG. 1, a ferroelectric gate thin film transistor 20 according to the embodiment 1 is a ferroelectric gate thin film transistor which includes: a channel layer 28; a gate electrode layer 22 which controls a conduction state of the channel layer 28; and a gate insulation layer 25 which is arranged between the channel layer 28 and the gate electrode layer 22 and is formed of a ferroelectric layer. The gate insulation layer (ferroelectric layer) 25 has the structure where a PZT layer 23 and a Pb diffusion preventing layer 24 formed of a BLT layer are laminated to each other. The channel layer 28 is formed of an ITO layer which constitutes an oxide conductor layer. The channel layer (oxide conductor layer) 28 is arranged on a surface of the gate insulation layer (ferroelectric layer) 25 on a Pb diffusion preventing layer 24 side. In FIG. 1, symbol 21 indicates an insulating substrate formed of an Si substrate on a surface of which an SiO₂ layer is formed, symbol 26 indicates a source electrode, and symbol 27 indicates a drain electrode. Symbol 10 indicates the laminated structure according to the present invention.

All of the PZT layer 23, the channel layer (oxide conductor layer) 28 and the Pb diffusion preventing layer 24 are manufactured using a liquid process. A thickness of the Pb diffusion preventing layer (BLT layer) 24 is set to a value which falls within a range of 10 nm to 30 nm, for example.

The ferroelectric gate thin film transistor 20 according to the embodiment 1 can be manufactured using a method described below. Hereinafter, the method is explained in the order of the following steps.

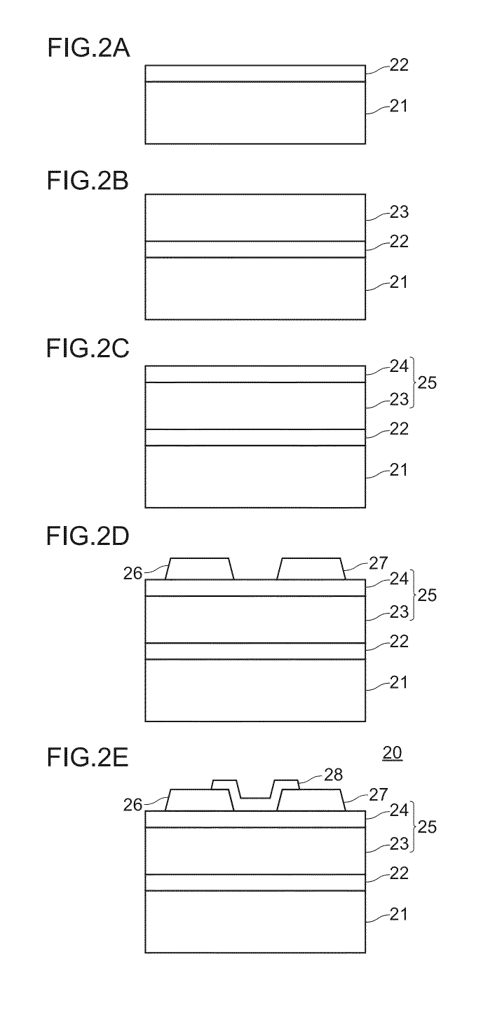

FIG. 2A to FIG. 2E are views for explaining a method of manufacturing the ferroelectric gate thin film transistor 20 according to the embodiment 1. FIG. 2A to FIG. 2E are views showing respective steps of the method.

### (1) Base Member Preparation Step

A base member is prepared where a gate electrode layer 22 formed of “a laminated film made of a Ti layer (10 nm) and a Pt layer (40 nm)” is formed on an insulating substrate 21 formed of an Si substrate on which an SiO₂ layer is formed (see FIG. 2A, made by TANAKA KIKINZOKU KOGYO K.K.). A plane size of the base member is 20 mm×20 mm.

### (2) Gate Insulation Layer Forming Step

### (2-1) PZT Layer Forming Step

A PZT sol-gel solution (made by Mitsubishi Materials Corporation, metal alkoxide type of 8 weight %, Pb:Zr:Ti=1.2:0.4:0.6) which becomes a PZT layer when heat treatment is applied to the solution is prepared.

Next, a precursor composition layer (layer thickness: 320 nm) of the PZT layer is formed by repeating four times “an operation where the above-mentioned PZT sol-gel solution is applied by coating to the gate electrode layer 22 using a spin coating method (for example, at 2500 rpm for 30 seconds) and, thereafter, the base member is placed on a hot plate and is dried in air at a temperature of 150° C. for 1 minute and, then, the base member is dried at a temperature of 250° C. for 5 minutes”.

Lastly, a PZT layer 23 (layer thickness: 160 nm) is formed by placing the precursor composition layer of the PZT layer on a hot plate having a surface temperature of 400° C. for 10 minutes and, thereafter, by applying heat treatment to the precursor composition layer of the PZT layer in air at a high temperature (at 650° C., for 15 minutes) using an RTA device (see FIG. 2B).

### (2-2) BLT Layer Forming Step

A BLT sol-gel solution (made by Mitsubishi Materials Corporation, metal alkoxide type of 5 weight %, Bi:La:Ti=3.40:0.75:3.0) which becomes a BLT layer when heat treatment is applied to the solution is prepared.

Next, the above-mentioned BLT sol-gel solution is applied by coating to the PZT layer 23 by a spin coating method (for example, at 2500 rpm for 30 seconds) and, thereafter, the base member is placed on a hot plate and is dried in air at a temperature of 150° C. for 1 minute and, then, is dried at a temperature of 250° C. for 5 minutes thus forming a precursor composition layer (layer thickness: 40 nm) of the BLT layer.

Lastly, the precursor composition layer of the BLT layer is placed on a hot plate having a surface temperature of 500° C. for 10 minutes and, thereafter, heat treatment is applied to the precursor composition layer of the BLT layer in an oxygen atmosphere at a high temperature (at 700° C., for 15 minutes) using an RTA device thus forming a BLT layer (Pb diffusion preventing layer) 24 (layer thickness: 20 nm) (see FIG. 2C).

### (3) Source Electrode/Drain Electrode Forming Step

The source electrode layer 26 and the drain electrode layer 27 both of which are made of Pt are formed on predetermined portions of a surface of the BLT layer (Pb diffusion preventing layer) 24 by a sputtering method and a photolithography method (see FIG. 2D).

### (4) Channel Layer Forming Step

Firstly, an ITO solution (functional liquid material (product name: ITO-05C) made by Kojundo Chemical Laboratory Co., Ltd., undiluted solution: diluted solution=1:1.5) containing metal carboxylate which becomes an ITO layer when heat treatment is applied to the solution is prepared. An impurity is added to the ITO solution at a concentration that a carrier concentration in the channel layer 28 at the time of completion of the channel layer 28 falls within a range of 1×10¹⁵ cm⁻³ to 1×10²¹ cm⁻³.

Next, an ITO solution is applied by coating to a surface of the BLT layer (Pb diffusion preventing layer) 24 by a spin coating method (for example, at 3000 rpm for 30 seconds) such that the ITO solution straddles over the source electrode layer 26 and the drain electrode layer 27. Thereafter, the base member is placed on a hot plate and is dried in air at a temperature of 150° C. for 1 minute and, then, is dried at a temperature of 250° C. for 5 minutes and, further, is dried at a temperature of 400° C. for 15 minutes thus forming a precursor composition layer (layer thickness: 40 nm) of the ITO layer.

Lastly, the precursor composition layer of the ITO layer is placed on the hot plate having a surface temperature of 250° C. for 10 minutes and, thereafter, the precursor composition layer is heated in air at a temperature of 450° C. for 30 minutes (in an oxygen atmosphere during a first half period of 15 minutes and in a nitrogen atmosphere during a second half period of 15 minutes) using an RTA device thus forming a channel layer 28 (layer thickness: 20 nm) (see FIG. 2E).

The ferroelectric gate thin film transistor 20 according to the embodiment 1 can be manufactured in accordance with the above-mentioned steps.

According to the ferroelectric gate thin film transistor 20 according to the embodiment 1, the Pb diffusion preventing layer formed of the BLT layer 24 exists between the PZT layer 23 and the ITO layer (channel layer) 28 and hence, as can be also understood from examples described later, a diffusion of Pb atoms into the ITO layer (channel layer) 28 from the PZT layer 23 can be prevented. Accordingly, it is possible to overcome various drawbacks which may be caused due to the diffusion of the Pb atoms into the oxide conductor layer from the PZT layer including a drawback that a transmission characteristic of the ferroelectric gate thin film transistor is liable to be lowered (for example, a drawback that a width of a memory window is liable to become narrow).

Further, according to the ferroelectric gate thin film transistor 20 of the embodiment 1, a thickness of the BLT layer (Pb diffusion preventing layer) 24 which constitutes the Pb diffusion preventing layer falls within a range of 10 nm to 30 nm (20 nm) and hence, the diffusion of Pb atoms into the ITO layer (channel layer) 28 from the PZT layer 23 can be prevented at a high level. Accordingly, it is possible to prevent at a higher level a drawback that a transmission characteristic of the ferroelectric gate thin film transistor is liable to be deteriorated (for example, a drawback that a width of a memory window is liable to become narrow, or a drawback that an OFF current is liable to be increased).

### Embodiment 2

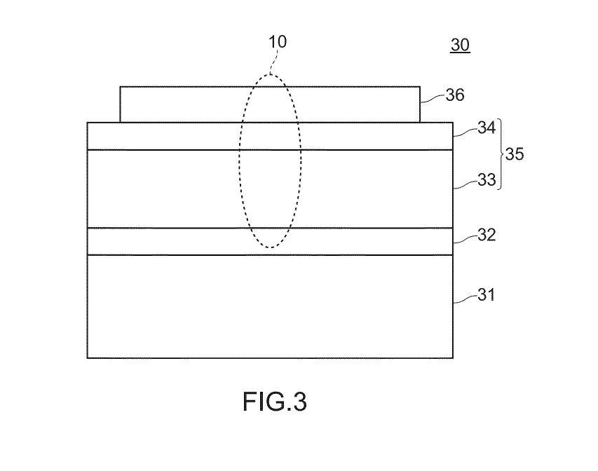

FIG. 3 is a view for explaining a ferroelectric thin film capacitor 30 according to the embodiment 2.

As shown in FIG. 3, the ferroelectric thin film capacitor 30 according to the embodiment 2 includes: a first electrode layer 32; a second electrode layer 36; and a dielectric layer 35 which is arranged between the first electrode layer 32 and the second electrode layer 36 and is formed of a ferroelectric layer. The dielectric layer (ferroelectric layer) 35 has the structure where a PZT layer 33 and a Pb diffusion preventing layer 34 formed of a BLT layer are laminated to each other. The second electrode layer 36 is formed of an ITO layer which constitutes an oxide conductor layer. The second electrode layer (oxide conductor layer) 36 is arranged on a surface of the dielectric layer (ferroelectric layer) 35 on a BLT layer (Pb diffusion preventing layer) 34 side. In FIG. 3, symbol 31 indicates an insulating base member formed of an Si substrate on a surface of which an SiO₂ layer formed. Symbol 10 indicates the laminated structure according to the present invention.

All of the PZT layer 33, the second electrode layer (ITO layer) 36 and the BLT layer (Pb diffusion preventing layer) 34 are manufactured by a liquid process. A thickness of the BLT layer (Pb diffusion preventing layer) 34 is set to a value which falls within a range of 10 nm to 30 nm, for example.

The ferroelectric thin film capacitor 30 according to the embodiment 2 can be manufactured by a method described below. Hereinafter, the method is explained in the order of the following steps.

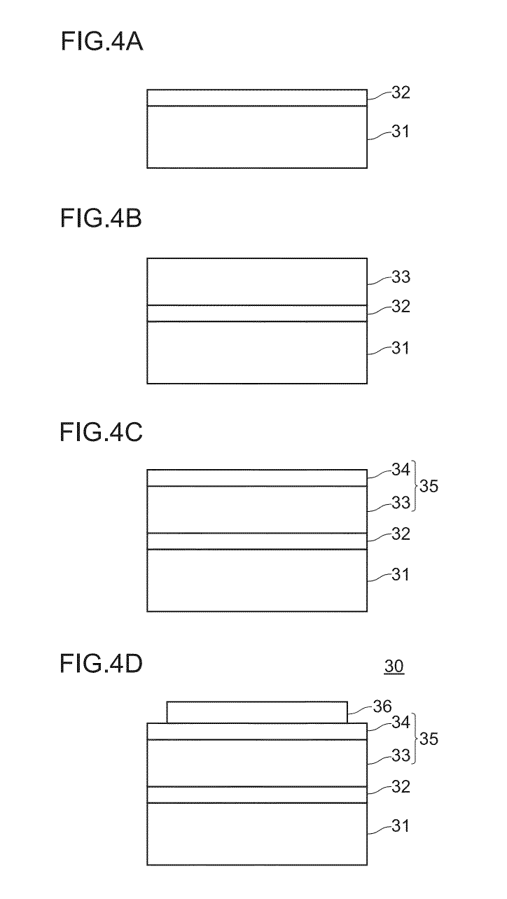

FIG. 4 A to FIG. 4D are views for explaining a method of manufacturing the ferroelectric thin film capacitor 30 according to the embodiment 2. FIG. 4A to FIG. 4D are views showing respective steps of the method.

### (1) Base Member Preparation Step

A base member is prepared where a first electrode layer 32 formed of “a laminated film made of Ti (10 nm) and Pt (40 nm)” is formed on an insulating substrate 31 formed of an Si substrate on a surface of which an SiO₂ layer is formed (see FIG. 4A, made by TANAKA KIKINZOKU KOGYO K.K.). A plane size of the base member is 20 mm×20 mm.

### (2) Dielectric Layer Forming Step

### (2-1) PZT Layer Forming Step

A PZT sol-gel solution (made by Mitsubishi Materials Corporation, metal alkoxide type of 8 weight %, Pb:Zr:Ti=1.2:0.4:0.6) which becomes a PZT layer when heat treatment is applied to the solution is prepared.

Next, a precursor composition layer (layer thickness: 320 nm) of the PZT layer is formed by repeating four times “an operation where the above-mentioned PZT sol-gel solution is applied by coating to the first electrode layer 32 by a spin coating method (for example, at 2500 rpm for 30 seconds) and, thereafter, the base member is placed on a hot plate and is dried in air at a temperature of 150° C. for 1 minute and, then, is dried at 250° C. for 5 minutes”.

Lastly, the precursor composition layer of the PZT layer is placed on the hot plate having a surface temperature of 400° C. for 10 minutes and, thereafter, heat treatment is applied to the precursor composition layer of the PZT layer in air at a high temperature (at 650° C., for 15 minutes) using an RTA device thus forming a PZT layer 33 (layer thickness: 160 nm) (see FIG. 4B).

### (2-2) BLT Layer Forming Step

A BLT sol-gel solution (made by Mitsubishi Materials Corporation, metal alkoxide type of 5 weight %, Bi:La:Ti=3.40:0.75:3.0) which becomes a BLT layer when heat treatment is applied to the solution is prepared.

Next, the above-mentioned BLT sol-gel solution is applied by coating to the PZT layer 33 by a spin coating method (for example, at 2500 rpm for 30 seconds) and, thereafter, the base member is placed on a hot plate and is dried in air at a temperature of 150° C. for 1 minute and, then, is dried at a temperature of 250° C. for 5 minutes thus forming a precursor composition layer (layer thickness: 40 nm) of the PZT layer.

Lastly, the precursor composition layer of the BLT layer is placed on the hot plate having a surface temperature of 500° C. for 10 minutes and, thereafter, heat treatment is applied to the precursor composition layer of the BLT layer in an oxygen atmosphere at a high temperature (at 700° C., for 15 minutes) using an RTA device thus forming a BLT layer (Pb diffusion preventing layer) 34 (layer thickness: 20 nm) (see FIG. 4C).

### (4) Second Electrode Layer Forming Step

Firstly, an ITO solution (functional liquid material (product name: ITO-05c) made by Kojundo Chemical Laboratory Co., Ltd., undiluted solution: diluted solution=1:1.5) containing metal carboxylate which becomes an ITO layer when heat treatment is applied to the solution is prepared. An impurity is added to the ITO solution at a concentration that a carrier concentration in the second electrode layer 36 at the time of completion of the second electrode layer 36 falls within a range of 1×10¹⁵ cm⁻³ to 1×10²¹ cm⁻³.

Next, a precursor composition layer (layer thickness: 160 nm) of the ITO layer is formed by repeating four times “an operation where an ITO solution is applied by coating to a surface of a BLT layer (Pb diffusion preventing layer) 34 by a spin coating method (for example, at 3000 rpm for 30 seconds) and, thereafter, the base member is placed on a hot plate and is dried in air at a temperature of 150° C. for 1 minute and, then, is dried at 250° C. for 5 minutes and, further, is dried at 400° C. for 15 minutes”.

Lastly, the precursor composition layer of the ITO layer is placed on the hot plate having a surface temperature of 250° C. for 10 minutes and, thereafter, the precursor composition layer is heated in air at a temperature of 450° C. for 30 minutes (in an oxygen atmosphere during a first half period of 15 minutes and in a nitrogen atmosphere during a second half period of 15 minutes) using an RTA device thus forming a second electrode layer 36 (layer thickness: 80 nm) formed of an ITO layer (see FIG. 4(d).

Due to the above-mentioned steps, the ferroelectric thin film capacitor 30 according to the embodiment 2 can be manufactured.

According to the ferroelectric thin film capacitor 30 of the embodiment 2, the Pb diffusion preventing layer formed of the BLT layer 34 exists between the PZT layer 33 and the ITO layer 36 and hence, a diffusion of Pb atoms into the second electrode layer (ITO layer) 36 from the PZT layer 33 can be prevented. Accordingly, it is possible to overcome a drawback that an electric characteristic of the ferroelectric thin film capacitor is liable to be deteriorated (for example, a drawback that the number of times that the capacitor can be charged/discharged is liable to be decreased).

Further, according to the ferroelectric thin film capacitor 30 of the embodiment 2, a thickness of the BLT layer 34 falls within a range of 10 nm to 30 nm (20 nm) and hence, the diffusion of Pb atoms into the second electrode layer (ITO layer) 36 from the PZT layer 33 can be prevented at a higher level. Accordingly, it is possible to overcome a drawback that an electric characteristic of the ferroelectric thin film capacitor is liable to be deteriorated (for example, the number of times that the capacitor can be charged/discharged is liable to be decreased) at a high level.

### Embodiment 3

### 1. Ferroelectric Gate Thin Film Transistor 100 According to the Embodiment 3

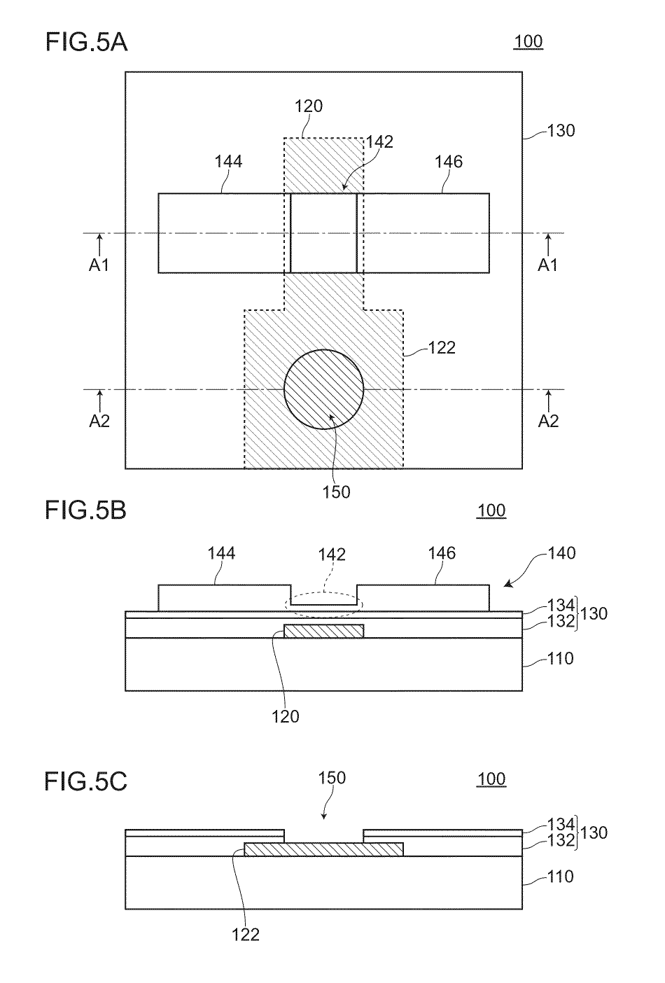

FIG. 5A to FIG. 5C are views for explaining a ferroelectric gate thin film transistor 100 according to the embodiment 3. FIG. 5A is a plan view of the ferroelectric gate thin film transistor 100, FIG. 5B is a cross-sectional view taken along a line A1-A1 in FIG. 5A, and FIG. 5C is a cross-sectional view taken along a line A2-A2 in FIG. 5A.

As shown in FIG. 5A and FIG. 5B, the ferroelectric gate thin film transistor 100 according to the embodiment 3 includes: an oxide conductor layer 140 having a source region 144, a drain region 146 and a channel region 142; a gate electrode 120 which controls a conduction state of the channel region 142; and a gate insulation layer 130 which is formed between the gate electrode 120 and the channel region 142 and is made of a ferroelectric material. A layer thickness of the channel region 142 is set smaller than a layer thickness of the source region 144 and a layer thickness of the drain region 146. The layer thickness of the channel region 142 is preferably ½ or less of the layer thickness of the source region 144 and the layer thickness of the drain region 146. As shown in FIG. 5A and FIG. 5C, the gate electrode 120 is connected to a gate pad 122 exposed to the outside through a through hole 150.

In the ferroelectric gate thin film transistor 100 according to the embodiment 3, the oxide conductor layer 140 where the layer thickness of the channel region 142 is set smaller than the layer thickness of the source region 144 and the layer thickness of the drain region 146 is formed using a press molding technique.

In the ferroelectric gate thin film transistor 100 according to the embodiment 3, a carrier concentration in the channel region 142 and a layer thickness of the channel region 142 are set to values such that the channel region 142 is depleted when a control voltage for turning off the ferroelectric gate thin film transistor 100 is applied to the gate electrode 120. To be more specific, the carrier concentration in the channel region 142 falls within a range of 1×10¹⁵ cm⁻³ to 1×10²¹ cm⁻³, and the layer thickness of the channel region 142 falls within a range of 5 nm to 100 nm.

In the ferroelectric gate thin film transistor 100 according to the embodiment 3, the layer thickness of the source region 144 and the layer thickness of the drain region 146 fall within a range of 50 nm to 1000 nm.

The oxide conductor layer 140 is made of indium tin oxide (ITO), for example. The gate insulation layer 130 is formed of a ferroelectric layer having the structure where a PZT layer 132 and a BLT layer 134 are laminated to each other, for example. A thickness of the PZT layer 132 is 160 nm, and a thickness of the BLT layer 134 is 20 nm. The gate electrode 120 and the gate pad 122 are made of lanthanum nickel oxide (LNO (LaNiO₃)), for example. The insulating substrate 110 is formed of an insulating substrate where an STO (SrTiO) layer is formed on a surface of an Si substrate with an SiO₂ layer and a Ti layer interposed therebetween, for example.

### 2. Method of Manufacturing Ferroelectric Gate Thin Film Transistor 100 According to Embodiment 3

The ferroelectric gate thin film transistor 100 according to the embodiment 3 can be manufactured by the following method of manufacturing a ferroelectric gate thin film transistor. Hereinafter, the method is explained in the order of the following steps.

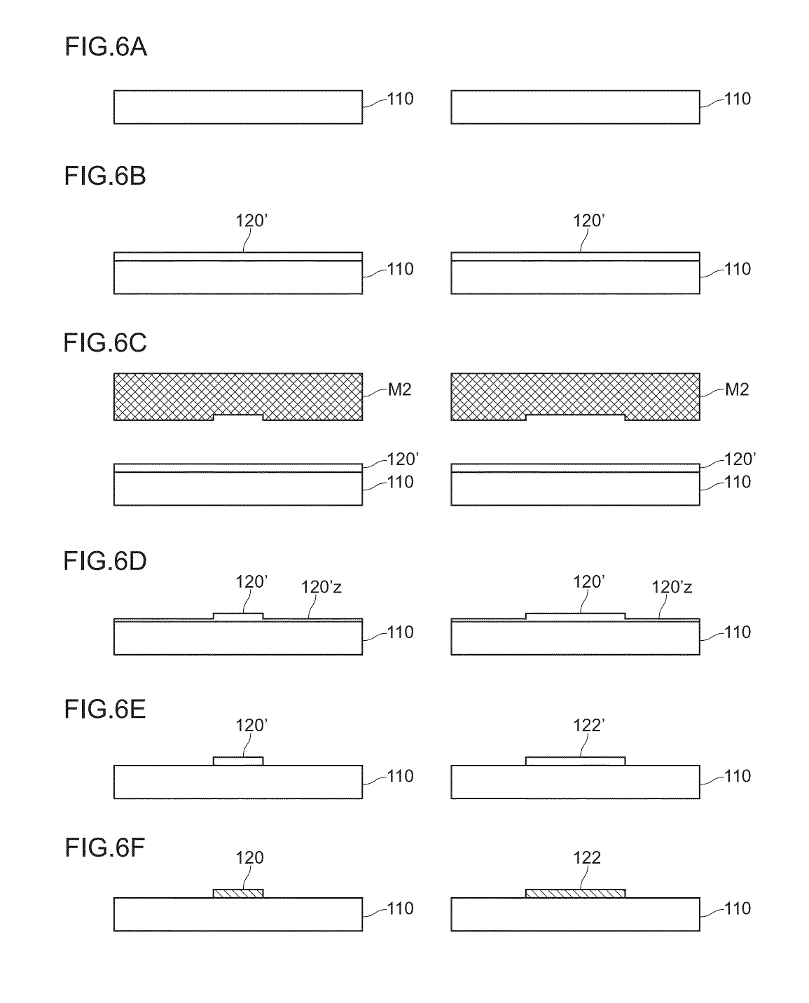

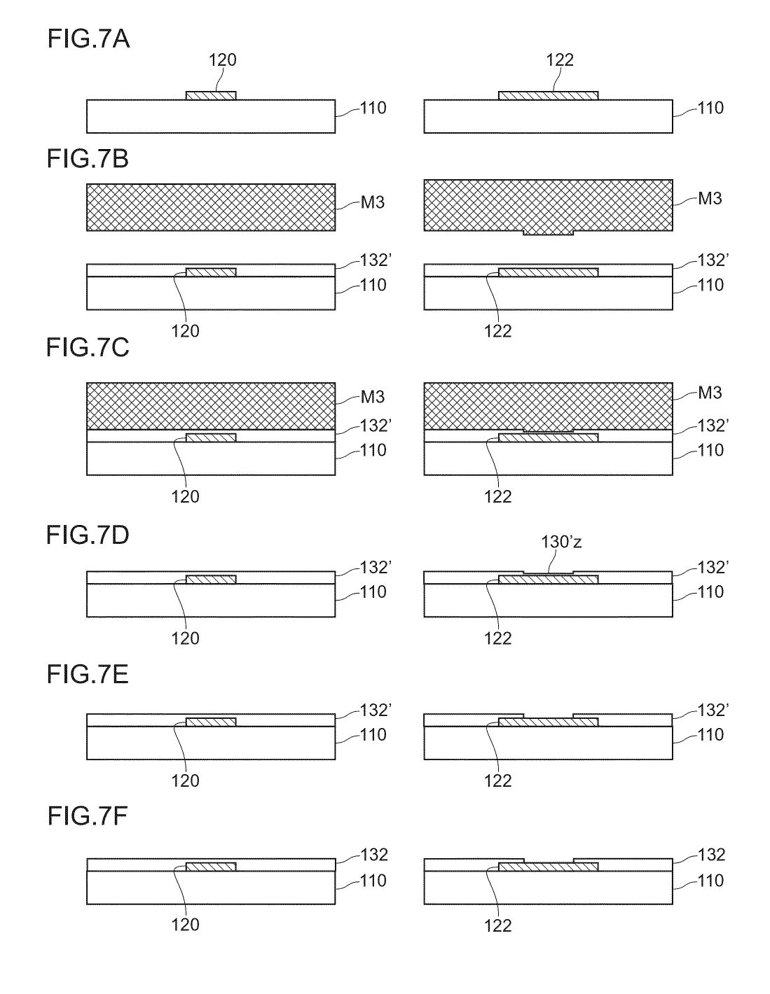

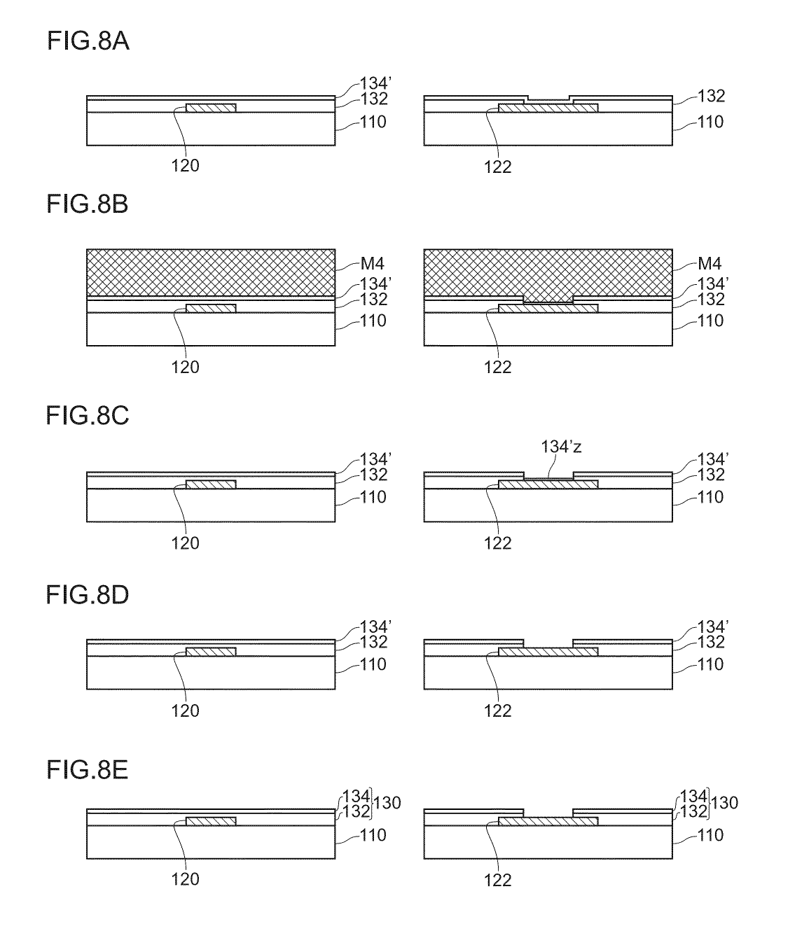

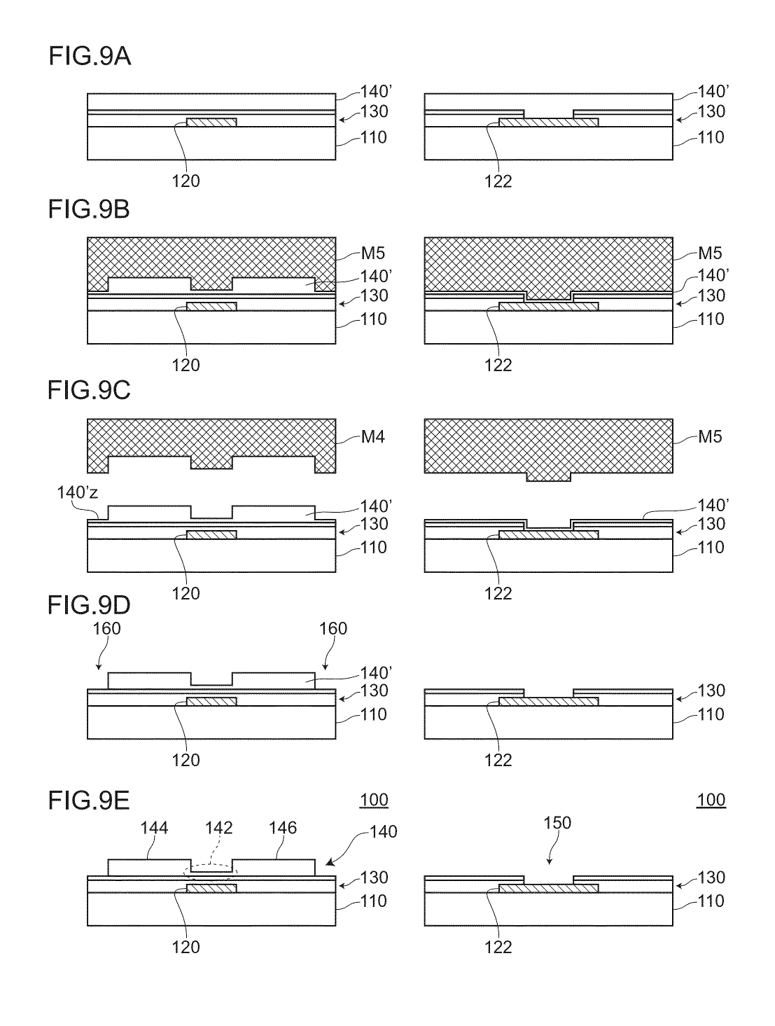

FIG. 6A to FIG. 9E are views for explaining the method of manufacturing the ferroelectric gate thin film transistor 100 according to the embodiment 3. FIG. 6A to FIG. 6F, FIG. 7A to FIG. 7F, FIG. 8A to FIG. 8E and FIG. 9A to FIG. 9E are views showing respective steps of the method. In the views showing respective steps of the method, the views on the left side are views which correspond to FIG. 5B, and the views on the right side are views which correspond to FIG. 5C.

### (1) Gate Electrode Forming Step

Firstly, a liquid material which becomes an LNO (lanthanum nickel oxide) layer when heat treatment is applied to the liquid material is prepared. To be more specific, an LNO solution (solvent: 2-methoxyethanol) containing metal inorganic salt (lanthanum nitrate (hexahydrate) and nickel acetate (tetrahydrate)) is prepared.

Next, as shown in FIG. 6A and FIG. 6B, a precursor composition layer 120′ (layer thickness: 300 nm) of an LNO (lanthanum nickel oxide) layer is formed by an operation where the LNO solution is applied by coating to one surface of the insulating substrate 110 by a spin coating method (for example, at 500 rpm for 25 seconds) and, thereafter, the insulating substrate 110 is placed on a hot plate and is dried at 60° C. for 1 minute.

Next, as shown in FIG. 6C and FIG. 6D, by applying the press molding to the precursor composition layer 120′ at a temperature of 150° C. using an uneven mold M2 which is formed such that regions of the uneven mold M2 corresponding to the gate electrodes 120 and the gate pads 122 are recessed (height difference: 300 nm), the press-molded structure (a layer thickness of a projecting portion: 300 nm, a layer thickness of a recessed portion: 50 nm) is formed on the precursor composition layer 120′. A pressure at the time of applying the press molding is set to 5 MPa.

Next, by etching the entire surface of the precursor composition layer 120′, as shown in FIG. 6E, the precursor composition layer is completely removed from regions other than regions corresponding to the gate electrodes 120 and the gate pads 122. The entire-surface etching step is performed using a wet etching technique while not using a vacuum process.

Lastly, heat treatment is applied to the precursor composition layer 120′ at a high temperature (at 650° C., for 10 minutes) using an RTA device thus, as shown in FIG. 6F, forming the gate electrode 120 and the gate pad 122 both of which are formed of the LNO (lanthanum nickel oxide) layer from the precursor composition layer 120′.

### (2) Gate Insulation Layer Forming Step

### (2-1) PZT Layer Forming Step

Firstly, a PZT sol-gel solution (made by Mitsubishi Materials Corporation, PZT sol-gel solution) which becomes a PZT when heat treatment is applied to the solution is prepared.

Next, as shown in FIG. 7A and FIG. 7B, a precursor composition layer 132′ (layer thickness: 300 nm) of the PZT layer is formed by repeating three times “an operation where the above-mentioned PZT sol-gel solution is applied by coating to one surface of the insulating substrate 110 by a spin coating method (for example, at 2000 rpm for 25 seconds) and, thereafter, an insulating substrate 110 is placed on a hot plate and is dried at 250° C. for 5 minutes”.

Next, as shown in FIG. 7B to FIG. 7D, by applying the press molding to the precursor composition layer 132′ at 150° C. using an uneven mold M3 which is formed such that a region of the uneven mold M3 corresponding to a through hole 150 projects (height difference: 300 nm), the press-molded structure corresponding to the through hole 150 is formed on the precursor composition layer 132′.

Next, by etching the entire surface of the precursor composition layer 132′, as shown in FIG. 7E, the precursor composition layer 132′ is completely removed from a region corresponding to the through hole 150. The entire surface etching step is performed using a wet etching technique while not using a vacuum process.

Lastly, heat treatment is applied to the precursor composition layer 132′ at a high temperature (at 650° C., for 10 minutes) using an RTA device thus, as shown in FIG. 7F, forming the PZT layer 132 (150 nm) from the precursor composition layer 132′.

### (2-2) BLT Layer Forming Step

Firstly, a BLT sol-gel solution (made by Kojundo Chemical Laboratory Co., Ltd., BLT sol-gel solution) which becomes a BLT layer when heat treatment is applied to the solution is prepared.

Next, as shown in FIG. 8A, the above-mentioned BLT sol-gel solution is applied by coating to the PZT layer 132 by a spin coating method (for example, at 2000 rpm for 25 seconds) and, thereafter, the insulating substrate 110 is placed on a hot plate and is dried at a temperature of 250° C. for 5 minutes thus forming a precursor composition layer 134′ (layer thickness: 40 nm) of a BLT layer.

Next, as shown in FIG. 8B and FIG. 8C, by applying the press molding to the precursor composition layer 134′ at a temperature of 150° C. using an uneven mold M4 which is formed such that a region of the uneven mold M4 corresponding to the through hole 150 projects, the press-molded structure corresponding to the through hole 150 is formed on the precursor composition layer 134′. In FIG. 8C, symbol 134′z indicates a residual film of the precursor composition layer 134′.

Next, by etching the entire surface of the precursor composition layer 134′, as shown in FIG. 8D, the precursor composition layer 134′ (residual film 134′z) is completely removed from a region corresponding to the through hole 150. The entire surface etching step is performed using a wet etching technique while not using a vacuum process.

Lastly, heat treatment is applied to the precursor composition layer 134′ at a high temperature (at 650° C., for 10 minutes) using an RTA device thus, as shown in FIG. 8E, forming the BLT layer 134 (layer thickness: 20 nm) from the precursor composition layer 134′.

### (3) Oxide Conductor Layer Forming Step

Firstly, an ITO solution (functional liquid material (product name: ITO-05C) made by Kojundo Chemical Laboratory Co., Ltd., undiluted solution: diluted solution=1:1.5) containing metal carboxylate which becomes an ITO layer when heat treatment is applied to the solution is prepared. An impurity is added to the ITO solution at a concentration that a carrier concentration in the channel region 142 at the time of completion of the channel region 142 falls within a range of 1×10¹⁵ cm⁻³ to 1×10²¹ cm⁻³.

Next, as shown in FIG. 9A, the above-mentioned ITO solution is applied by coating to one surface of the insulating substrate 110 by a spin coating method (for example, at 2000 rpm for 25 seconds) and, thereafter, the insulating substrate 110 is placed on a hot plate and is dried at a temperature of 150° C. for 3 minutes thus forming a precursor composition layer 140′ of an ITO layer.

Next, as shown in FIG. 9B and FIG. 9C, by applying the press molding to the precursor composition layer 140′ using an uneven mold M5 which is formed such that a region of the uneven mold M5 corresponding to a channel region 142 projects more than regions of the uneven mold M5 corresponding to a source region 144 and a drain region 146 (height difference: 350 nm), the press-molded structure (a layer thickness of a projecting portion: 350 nm, a layer thickness of a recessed portion: 100 nm) is formed on the precursor composition layer 140′. Due to such press molding, a portion of the precursor composition layer 140′ which becomes a channel region 142 has a smaller layer thickness than other portions of the precursor composition layer 140′.

The uneven mold M5 has the structure where regions of the uneven mold M5 corresponding to the element separation region 160 (see FIG. 9D) and the through hole 150 (see FIG. 9E) project more than the region of the uneven mold M5 corresponding to the channel region 142. Accordingly, by applying wet etching to one entire surface of the insulating substrate 110, the precursor composition layer 140′ can be completely removed from the regions corresponding to the element separation region 160 and the through hole 150 while making a portion which becomes the channel region 142 have a predetermined thickness (see FIG. 9D). The uneven mold M5 may have a shape where a portion corresponding to the element separation region is tapered.

Lastly, heat treatment is applied to the precursor composition layer 140′ (the precursor composition layer 140′ is baked on a hot plate at 400° C. for 10 minutes and, thereafter, the precursor composition layer 140′ is heated at a temperature of 650° C. for 30 minutes (in an oxygen atmosphere during a first half period of 15 minutes and in a nitrogen atmosphere during a second half period of 15 minutes) using an RTA device thus forming the oxide conductor layer 140 having the source region 144, the drain region 146 and the channel region 142 whereby the ferroelectric gate thin film transistor 100 according to the embodiment 3 having the bottom gate structure shown in FIG. 9E can be manufactured.

### 3. Advantageous Effect of Ferroelectric Gate Thin Film Transistor 100 According to Embodiment 3

According to the ferroelectric gate thin film transistor 100 of the embodiment 3, an oxide conductive material is used as a material for forming the channel region 142 and hence, a carrier concentration in the channel region 142 can be increased. Further, a ferroelectric material is used as a material for forming the gate insulation layer 130 and hence, switching of the ferroelectric gate thin film transistor 100 can be performed at a low drive voltage at a high speed. As a result, in the same manner as the conventional ferroelectric gate thin film transistor 900, it is possible to control a large electric current at a low drive voltage at a high speed. Further, a ferroelectric material is used as a material for forming the gate insulation layer 130 and hence, the ferroelectric gate thin film transistor 100 has a favorable hysteresis characteristic whereby the ferroelectric gate thin film transistor 100 can be suitably used as a memory element or a battery element in the same manner as the conventional ferroelectric gate thin film transistor 900.

Further, according to the ferroelectric gate thin film transistor 100 of the embodiment 3, the ferroelectric gate thin film transistor can be manufactured by merely forming the oxide conductor layer 140 where the layer thickness of the channel region 142 is set smaller than the layer thickness of the source region 144 and the layer thickness of the drain region 146. Accordingly, unlike the conventional ferroelectric gate thin film transistor 900, it becomes unnecessary to form the channel region using a material different from a material for forming the source region and the drain region and hence, the excellent ferroelectric gate thin film transistor described above can be manufactured using considerably smaller amounts of raw materials and a considerably smaller amount of manufacturing energy compared to the the conventional manufacturing method and, at the same time, using shorter steps compared to the conventional method.

Further, according to the ferroelectric gate thin film transistor 100 of the embodiment 3, all of the oxide conductor layer, the gate electrode and the gate insulation layer are formed using a liquid process and hence, the ferroelectric gate thin film transistor can be manufactured using a press molding technique whereby the excellent ferroelectric gate thin film transistor described above can be manufactured using considerably smaller amounts of raw materials and a considerably smaller amount of manufacturing energy compared to the conventional manufacturing method and, at the same time, using shorter steps compared to the conventional method.

According to the ferroelectric gate thin film transistor 100 of the embodiment 3, the Pb diffusion preventing layer formed of the BLT layer 134 exists between the PZT layer 132 and the oxide conductor layer 140 (the source region 144, the drain region 146 and the channel region 142) and hence, as can be also understood from examples described later, a diffusion of Pb atoms into the ITO layer 142 from the PZT layer 132 can be prevented. Accordingly, it is possible to overcome various drawbacks which may be caused due to the diffusion of the Pb atoms into the oxide conductor layer from the PZT layer including a drawback that a transmission characteristic of the ferroelectric gate thin film transistor is liable to be lowered (for example, a width of a memory window is liable to become narrow).

Further, according to the ferroelectric gate thin film transistor 100 of the embodiment 3, a thickness of the BLT layer 134 falls within a range of 10 nm to 30 nm (20 nm) and hence, the diffusion of Pb atoms into the ITO layer 142 from the PZT layer 132 can be prevented at a high level. Accordingly, it is possible to overcome various drawbacks which may be caused due to the diffusion of the Pb atoms into the oxide conductor layer from the PZT layer including a drawback that a transmission characteristic of the ferroelectric gate thin film transistor is liable to be lowered (for example, a width of a memory window is liable to become narrow). Further, it is possible to overcome a drawback that a transmission characteristic of the ferroelectric gate thin film transistor may be deteriorated (for example, an ON current is lowered or an OFF current is increased).

### Embodiment 4

Although a ferroelectric gate thin film transistor 102 (not shown in the drawing) according to the embodiment 4 basically has the same constitution as the ferroelectric gate thin film transistor 100 according to the embodiment 3, the ferroelectric gate thin film transistor 102 according to the embodiment 4 differs from the ferroelectric gate thin film transistor 100 according to the embodiment 3 with respect to a point that the ferroelectric gate thin film. transistor 102 includes an LaTaOx layer as a Pb diffusion preventing layer in place of the BLT layer. Further, the ferroelectric gate thin film transistor 102 according to the embodiment 4 is manufactured by the method substantially equal to the method of manufacturing the ferroelectric gate thin film transistor 100 according to the embodiment 3 except for that the following LaTaOx layer forming step is performed in place of the BLT layer forming step. Accordingly, only the LaTaOx layer forming step in the method of manufacturing the ferroelectric gate thin film transistor 102 according to the embodiment 4 is explained hereinafter.

(2-2) LaTaOx layer forming step

Firstly, a liquid material which becomes an LaTaOx layer when heat treatment is applied to the liquid material is prepared. To be more specific, an LaTaOx solution (solvent: propionic acid) containing lanthanum acetate and Ta butoxide is prepared.

Next, the above-mentioned LaTaOx solution is applied by coating to the PZT layer by a spin coating method (for example, 2000 rpm for 25 seconds) and, thereafter, the insulating substrate is placed on a hot plate and is dried in air at a temperature of 250° C. for 5 minutes thus forming a precursor composition layer (layer thickness: 40 nm) of the LaTaOx layer.

Next, by applying the press molding to the precursor composition layer at a temperature of 150° C. using an uneven mold which is formed such that a region of the uneven mold corresponding to a through hole projects, the press-molded structure corresponding to the through hole 150 is formed on the precursor composition layer.

Next, by etching the entire surface of the precursor composition layer, the precursor composition layer (residual film) is completely removed from a region corresponding to the through hole. The entire surface etching step is performed using a wet etching technique while not using a vacuum process.

Lastly, the precursor composition layer of the LaTaOx layer is placed on the hot plate having a surface temperature of 250° C. for 10 minutes and, thereafter, heat treatment is applied to the precursor composition layer of the LaTaOx layer in an oxygen atmosphere at a high temperature (at 550° C., for 10 minutes) using an RTA device thus forming an LaTaOx layer (Pb diffusion preventing layer) (layer thickness: 20 nm) from the precursor composition layer.

In this manner, the ferroelectric gate thin film transistor 102 according to the embodiment 4 differs from the ferroelectric gate thin film transistor 100 according to the embodiment 3 with respect to the constitution of the Pb diffusion preventing layer. However, an oxide conductive material is used as a material for forming the channel region and hence, a carrier concentration in the channel region can be increased. Further, a ferroelectric material is used as a material for forming the gate insulation layer and hence, switching of the ferroelectric gate thin film transistor 102 can be performed at a low drive voltage at a high speed. As a result, in the same manner as the conventional ferroelectric gate thin film transistor 900, it is possible to control a large electric current at a low drive voltage at a high speed. Further, a ferroelectric material is used as a material for forming the gate insulation layer and hence, the ferroelectric gate thin film transistor 102 has a favorable hysteresis characteristic whereby the ferroelectric gate thin film transistor 102 can be suitably used as a memory element or a battery element in the same manner as the conventional ferroelectric gate thin film transistor 900.

The ferroelectric gate thin film transistor can be manufactured by merely forming the oxide conductor layer where the layer thickness of the channel region is set smaller than the layer thickness of the source region and the layer thickness of the drain region. Accordingly, unlike the conventional ferroelectric gate thin film transistor 900, it becomes unnecessary to form the channel region using a material different from a material for forming the source region and the drain region and hence, the excellent ferroelectric gate thin film transistor described above can be manufactured using considerably smaller amounts of raw materials and a considerably smaller amount of manufacturing energy compared to the conventional manufacturing method and, at the same time, using shorter steps compared to the conventional method.

Further, all of the oxide conductor layer, the gate electrode and the gate insulation layer are formed using a liquid process and hence, the ferroelectric gate thin film transistor can be manufactured using a press molding technique whereby the excellent ferroelectric gate thin film transistor described above can be manufactured using considerably smaller amounts of raw materials and a considerably smaller amount of manufacturing energy compared to the conventional manufacturing method and, at the same time, using shorter steps compared to the conventional method.

Further, the Pb diffusion preventing layer formed of an LaTaOx layer exists between the PZT layer and the oxide conductor layer (the source region, the drain region and the channel region) and hence, a diffusion of Pb atoms into the ITO layer from the PZT layer can be prevented. Accordingly, it is possible to overcome various drawbacks which may be caused due to the diffusion of the Pb atoms into the oxide conductor layer from the PZT layer including a drawback that a transmission characteristic of the ferroelectric gate thin film transistor is liable to be lowered (for example, a width of a memory window is liable to become narrow).

Further, a thickness of the LaTaOx layer falls within a range of 10 nm to 30 nm (20 nm) and hence, the diffusion of Pb atoms into the ITO layer from the PZT layer can be prevented at a higher level. Accordingly, it is possible to overcome various drawbacks which may be caused due to the diffusion of the Pb atoms into the oxide conductor layer from the PZT layer including a drawback that a transmission characteristic of the ferroelectric gate thin film transistor is liable to be lowered (for example, a width of a memory window is liable to become narrow) at a higher level. Further, it is possible to overcome a drawback that a transmission characteristic of the ferroelectric gate thin film transistor is liable to be deteriorated (for example, an ON current is lowered or an OFF current is increased).

### Example 1

The example 1 is an example showing that the diffusion of Pb atoms into an ITO layer from a PZT layer is prevented when a BLT layer is interposed between the PZT layer and the ITO layer.

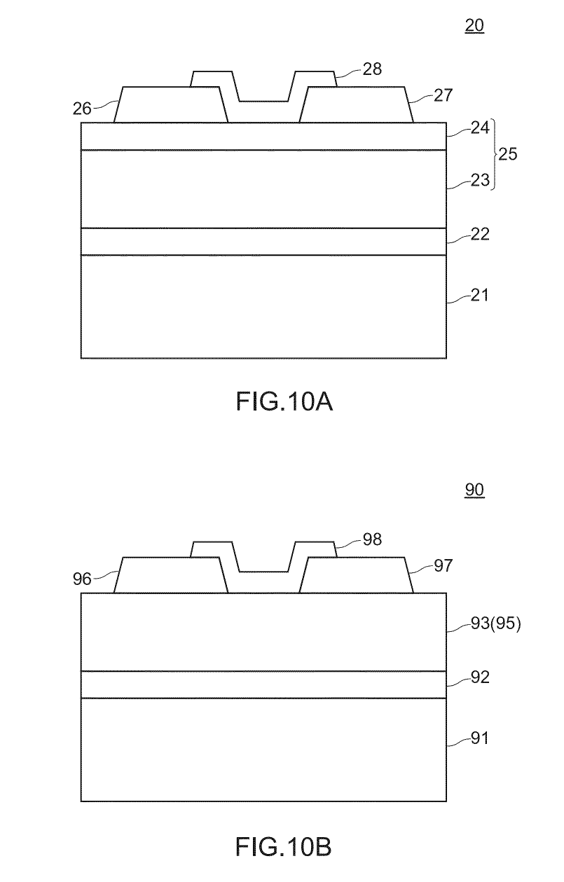

FIG. 10A to FIG. 14B are views for explaining ferroelectric gate thin film transistors 20, 90 according to test examples 1, 2. The ferroelectric gate thin film transistor 20 according to the test example 1 is an example, and the ferroelectric gate thin film transistor according to the test example 2 is a comparison example.

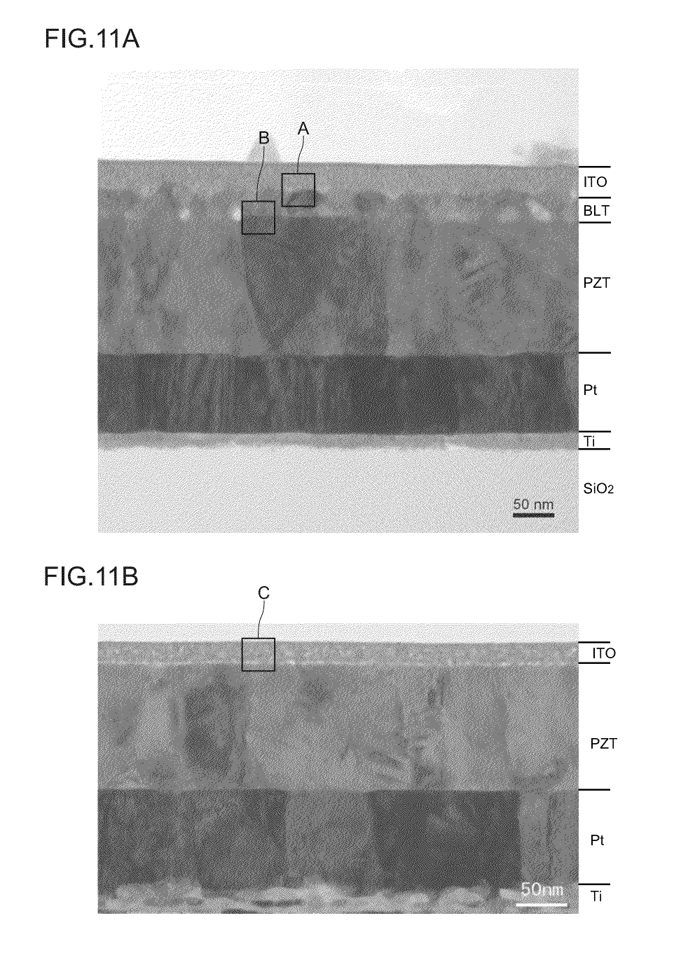

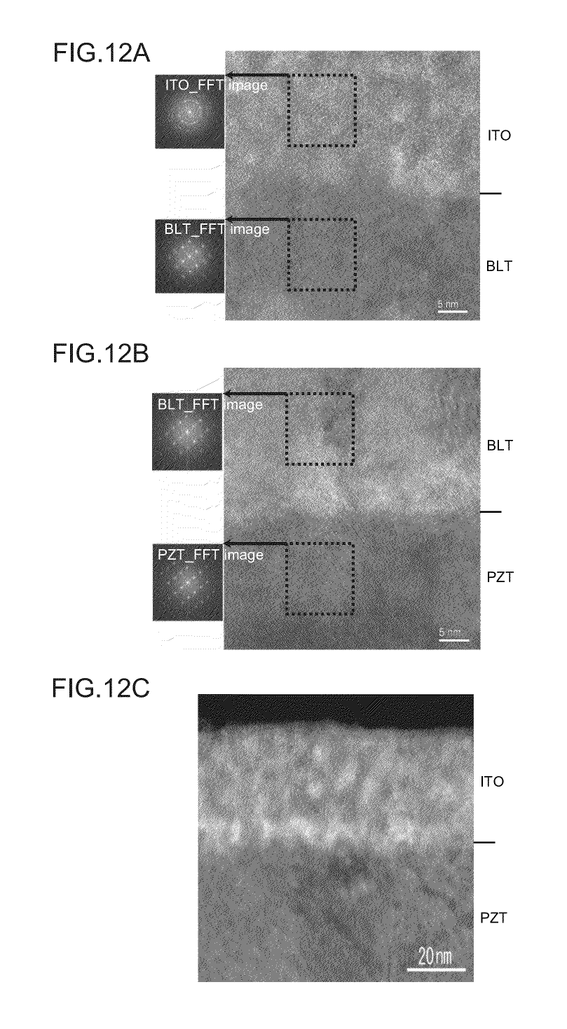

FIG. 10A is a cross-sectional view of the ferroelectric gate thin film transistor 20 according to the test example 1, and FIG. 10B is a cross-sectional view of the ferroelectric gate thin film transistor 90 according to the test example 2. FIG. 11A is a cross-sectional TEM photograph of the ferroelectric gate thin film transistor 20 according to the test example 1, and FIG. 11B is a cross-sectional TEM photograph of the ferroelectric gate thin film transistor 90 according to the test example 2. FIG. 12A is a partially enlarged view of a portion indicated by symbol A in FIG. 11A, FIG. 12B is a partially enlarged view of a portion indicated by symbol B in FIG. 11A, and FIG. 12C is a partially enlarged view of a portion indicated by symbol C in FIG. 11B. In FIG. 12A and FIG. 12B, results of the electron beam diffraction are shown in a small manner in a region on the left side of the drawing.

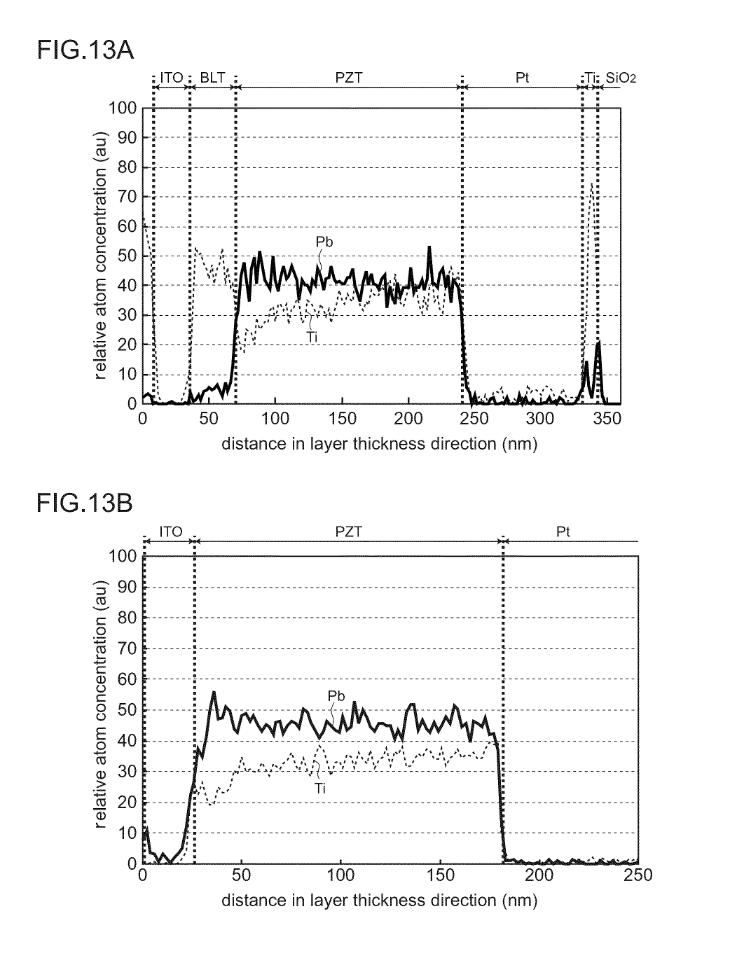

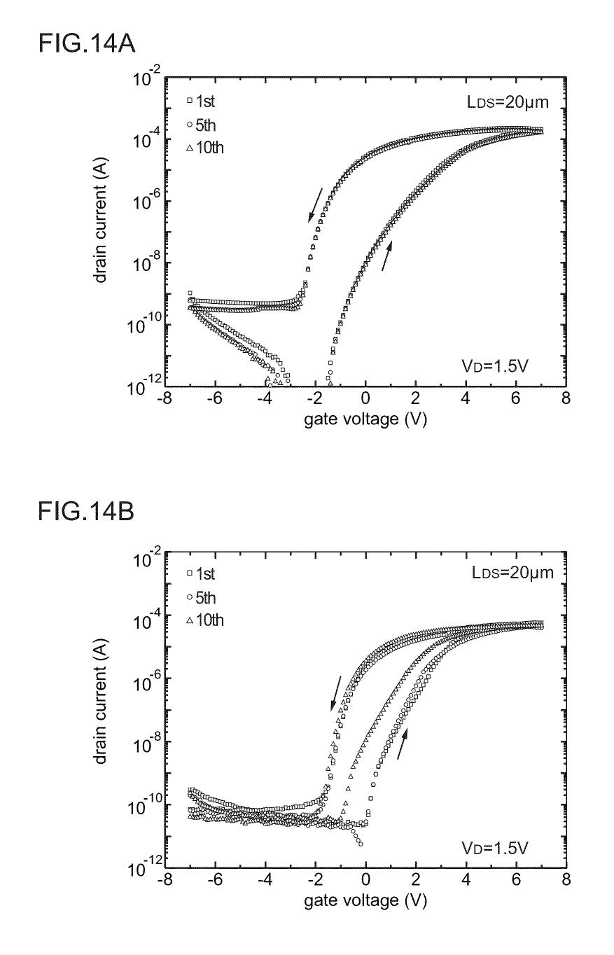

FIG. 13A is a graph showing an EDX spectrum of the ferroelectric gate thin film transistor 20 according to the test example 1, and FIG. 13B is a graph showing an EDX spectrum of the ferroelectric gate thin film transistor 90 according to the test example 2. FIG. 14A is a graph showing a transmission characteristic of the ferroelectric gate thin film transistor 20 according to the test example 1, and FIG. 14B is a graph showing a transmission characteristic of the ferroelectric gate thin film transistor 90 according to the test example 2.

### 1. Preparation of Specimen

The ferroelectric gate thin film transistor 20 according to the embodiment 1 is directly used as a ferroelectric gate thin film transistor according to the test example 1 (see FIG. 1 and FIG. 10A). Here, a thickness of a PZT layer 23 is set to 160 nm, and a thickness of a BLT layer is set to 20 nm. A ferroelectric gate thin film transistor obtained by removing the BLT layer from the ferroelectric gate thin film transistor 20 according to the embodiment 1 is used as the ferroelectric gate thin film transistor 90 according to the test example 2 (see FIG. 10B). Here, a thickness of a PZT layer 93 is set to 160 nm.

### 2. Cross-Sectional TEM Observation of Specimen and EDX Spectrum Measurement

Thin films for measurement are prepared from the ferroelectric gate thin film transistor 20 according to the test example 1 and the ferroelectric gate thin film transistor 90 according to the test example 2, and TEM photographs are obtained using a transmission electron microscope “JSM-2100F” made by JEOL Ltd. Further, EDX spectrums (energy dispersion type X ray spectroscopic spectrums) are obtained using an energy dispersion type X-ray analyzer “JED-2300T” made by JEOL Ltd.

As a result, “an interface between the PZT layer 23 and the BLT layer 24” and “an interface between the BLT layer 24 and the ITO layer (channel layer) 28” in the ferroelectric gate thin film transistor 20 according to the test example 1″ and “an interface between the PZT layer 93 and the ITO layer 98 in the ferroelectric gate thin film transistor 90 according to the test example 2” cannot be clearly observed from the respective cross-sectional TEM photographs (see FIG. 12A, FIG. 12B and FIG. 12C). However, as can be also understood from FIG. 13A and FIG. 13B, it is confirmed that Pb atoms are diffused into the ITO layer 98 from the PZT layer 93 (Pb atoms diffused approximately 10 nm) in the ferroelectric gate thin film transistor 90 according to the test example 2, while the diffusion of Pb atoms from the PZT layer 23 is stopped at the BLT layer 24 in the ferroelectric gate thin film transistor 20 according to the test example 1 so that the Pb atoms are not diffused into the ITO layer (channel layer) 28.

As can be also understood from an electron beam diffraction photograph shown in FIG. 12A and an electron beam diffraction photograph shown in FIG. 12B, a crystalline spot is observed in both the PZT layer 23 and the BLT layer 24 so that it is confirmed that both the PZT layer 23 and the BLT layer 24 have favorable crystallinity.

### 4. Transmission Characteristic of Specimen

Firstly, end portions of the PZT layer 23 and the BLT layer (Pb diffusion preventing layer) 24 are removed by wet etching so that the gate electrode layer 22 is exposed and a probe for the gate electrode layer is brought into pressure contact with the exposed gate electrode layer 22. Thereafter, a probe for source is brought into contact with the source electrode layer 26 and a probe for drain is brought into contact with the drain electrode layer 27 so that a transmission characteristic (an I_{D}−V_{G} characteristic between a drain current I_{D} and a gate voltage V_{G}) of the ferroelectric gate thin film transistor 20 is measured using a semiconductor parameter analyzer (made by Agilent Technologies, Inc.). The transmission characteristic (I_{D}−V_{G} characteristic) is measured in such a state where a drain voltage V_{D} is fixed to 1.5V and a gate voltage V_{G} is scanned within a range of −7V to +7V. The same evaluation is performed also with respect to the ferroelectric gate thin film transistor 90.

As a result, it is found that a transmission characteristic (for example, a width of a memory window) of the ferroelectric gate thin film transistor is deteriorated due to a voltage scanning of 10 times in the ferroelectric gate thin film transistor 90 according to the test example 2 (see FIG. 14B), while a transmission characteristic (for example, a width of a memory window) of the ferroelectric gate thin film transistor is not deteriorated due to a voltage scanning of 10 times in the ferroelectric gate thin film transistor 20 according to the test example 1 (see FIG. 14A).

From the above-mentioned result, it is found that when the BLT layer is interposed between the PZT layer and the ITO layer, a diffusion of Pb atoms into the ITO layer from the PZT layer can be prevented so that a drawback that a transmission characteristic of the ferroelectric gate thin film transistor is liable to be lowered (for example, a width of a memory window is liable to become narrow) can be overcome.

### Example 2

The example 2 is an example showing a transmission characteristic of the respective ferroelectric gate thin film transistor in cases where a thickness of a PZT layer and a thickness of a BLT layer are changed respectively.

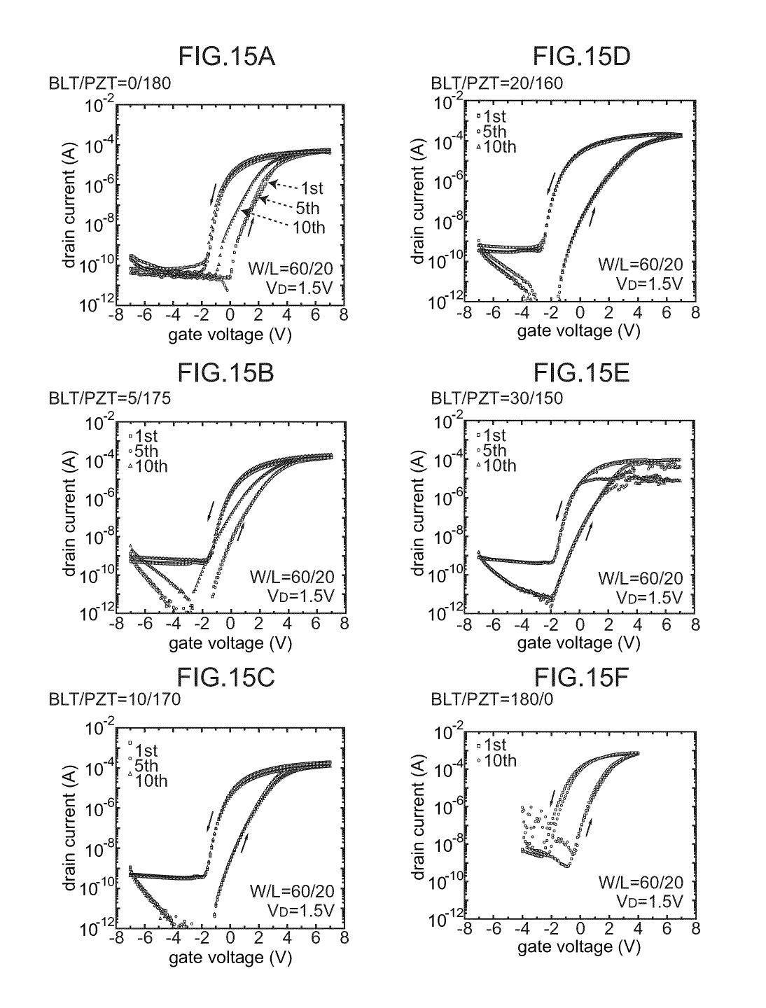

FIG. 15A to FIG. 15F are views showing a transmission characteristic of respective ferroelectric gate thin film transistors according to the example 2 (a ferroelectric gate thin film transistor 20a according to the test example 3 to a ferroelectric gate thin film transistor 20f according to the test example 8).

### 1. Preparation of Specimen

The ferroelectric gate thin film transistor 20 according to the embodiment 1 is directly used as respective ferroelectric gate thin film transistors according to the example 2 (the ferroelectric gate thin film transistor 20a according to the test example 3 to the ferroelectric gate thin film transistor 20f according to the test example 8).

In the ferroelectric gate thin film transistor 20a according to the test example 3, a thickness of a PZT layer 23 is set to 180 nm, and a thickness of a BLT layer is set to 0 nm. In the ferroelectric gate thin film transistor 20b according to the test example 4, a thickness of a PZT layer 23 is set to 175 nm, and a thickness of a BLT layer is set to 5 nm. In the ferroelectric gate thin film transistor 20c according to the test example 5, a thickness of a PZT layer 23 is set to 170 nm, and a thickness of a BLT layer is set to 10 nm. In the ferroelectric gate thin film transistor 20d according to the test example 6, a thickness of a PZT layer 23 is set to 160 nm, and a thickness of a BLT layer is set to 20 nm. In the ferroelectric gate thin film transistor 20e according to the test example 7, a thickness of a PZT layer 23 is set to 150 nm, and a thickness of a BLT layer is set to 30 nm. In the ferroelectric gate thin film transistor 20f according to the test example 8, a thickness of a PZT layer 23 is set to 0 nm, and a thickness of a BLT layer is set to 180 nm. The ferroelectric gate thin film transistor 20c according to the test example 5, the ferroelectric gate thin film transistor 20d according to the test example 6 and the ferroelectric gate thin film transistor 20e according to the test example 7 are the examples, and the ferroelectric gate thin film transistor 20a according to the test example 3, the ferroelectric gate thin film transistor 20b according to the test example 4 and the ferroelectric gate thin film transistor 20f according to the test example 8 are the comparison examples.

### 2. Transmission Characteristic of Specimen

A transmission characteristic of the respective ferroelectric gate thin film transistors 20a to 20f is measured by the same method as the case of the example 1.

As a result, in the ferroelectric gate thin film transistor 20a according to the test example 3 and the ferroelectric gate thin film transistor 20b according to the test example 4, a transmission characteristic (a width of a memory window) is largely deteriorated due to a voltage scanning of 10 times. On the other hand, in the ferroelectric gate thin film transistor 20c according to the test example 5 to the ferroelectric gate thin film transistor 20e according to the test example 7, a transmission characteristic (a width of a memory window) is not deteriorated due to a voltage scanning of 10 times. In the ferroelectric gate thin film transistor 20f according to the test example 8, although a width of a memory window is not narrowed, a tendency is observed that an OFF current is increased.

From the above-mentioned results, it is found that when the BLT layer having a thickness which falls within a range of 10 nm to 30 nm is interposed between the PZT layer and the ITO layer, a diffusion of Pb atoms into the ITO layer from the PZT layer can be prevented so that a drawback that a transmission characteristic of the ferroelectric gate thin film transistor is liable to be lowered (for example, a width of a memory window is liable to become narrow) can be overcome.

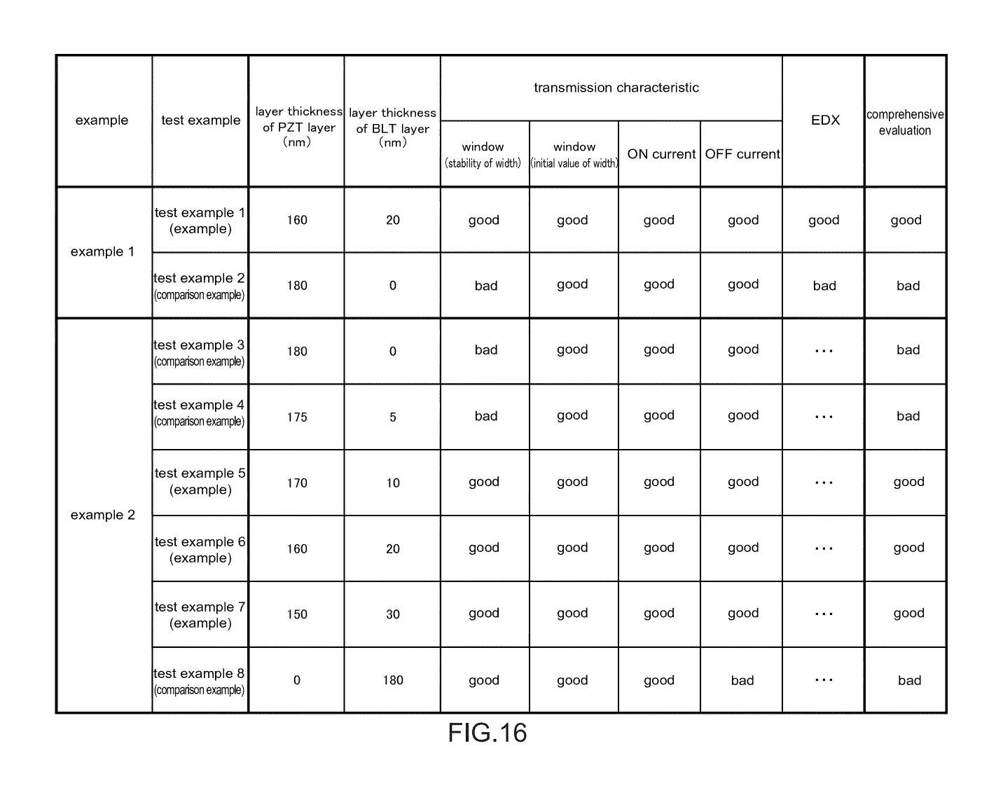

FIG. 16 is a Table collectively showing results of the example 1 and the example 2. In FIG. 16, with respect to a transmission characteristic, “good” is given to a ferroelectric gate thin film transistor having the transmission characteristic at a level usable as a ferroelectric gate thin film transistor, while “bad” is given to a ferroelectric gate thin film transistor having the transmission characteristic at a level unusable as a ferroelectric gate thin film transistor. Further, with respect to an EDX, “good” is given when Pb atoms are not diffused into the ITO layer from the PZT layer, and “bad” is given when Pb atoms are diffused into the ITO layer from the PZT layer.

As can be also understood from FIG. 16, according to the ferroelectric gate thin film transistor according to the present invention, it is confirmed that it is possible to overcome various drawbacks which may be caused due to the diffusion of the Pb atoms into the ITO layer from the PZT layer including a drawback that Pb atoms are diffused into the ITO layer from the PZT layer and a drawback that a transmission characteristic of the ferroelectric gate thin film transistor is liable to be lowered (for example, a width of a memory window is liable to become narrow).

Although the laminated structure, the ferroelectric gate thin film transistor and the ferroelectric thin film capacitor according to the present invention have been explained heretofore by reference to the above-mentioned embodiments, the present invention is not limited to the above-mentioned embodiments, and can be carried out without departing from the gist according to the present invention so that the following modifications are conceivable, for example.

(1) Although ITO (indium tin oxide) is used as an oxide conductor material in the above-mentioned respective embodiments, the present invention is not limited to ITO. In—0 (indium oxide) or IGZO can be favorably used. Further, it is possible to use an oxide conductor material such as antimony-doped tin oxide (Sb—SnO₂). zinc oxide (ZnO), aluminum-doped zinc oxide (Al—ZnO), gallium-doped zinc oxide (Ga—ZnO), ruthenium oxide (RuO₂), Iridium oxide (IrO₂), stannic oxide (SnO₂), stannous oxide (SnO), or niobium-doped titanium dioxide (Nb—TiO₂). Further, it is also possible to use amorphous conductive oxide such as gallium-doped indium oxide (In—Ga—O (IGO)) or indium-doped zinc oxide (In—Zn—O (IZO)). It is also possible to use strontium titanate (SrTiO₃), niobium-doped strontium titanate (Nb—SrTiO₃), strontium barium complex oxide (SrBaO₃), strontium calcium complex oxide (SrCaO₃), ruthenium acid strontium (SrRuO₃), lanthanum nickel oxide (LaNiO₃), titania lanthanum (LaTiO₃), lanthanum copper oxide (LaCuO₃), nickel oxide neodymium (NdNiO₃), nickel oxide yttrium (YNiO₃), lanthanum oxide calcium manganese complex oxide (LCMO), plumbic acid barium (BaPbO₃), LSCO (LaₓSr₁₋ₓCuO₃), LSMO (La₁₋ₓSrₓMnO₃), YBCO (YBa₂Cu₃O₇₋ₓ), LNTO (La(NI₁₋ₓTiₓ)O₃), LSTO ((La₁₋ₓ, Srₓ)TiO₃), STRO (Sr(Ti₁₋ₓRuₓ)O₃), a perovskite-type conductive oxides or a pyrochlore-type conductive oxide.

(2) Although an LaTaOx layer is used as the Pb diffusion preventing layer in the embodiment 4, the present invention is not limited to the LaTaOx layer. For example, an LaZrOx layer or an SrTaOx layer can be preferably used in place of the LaTaOx layer.

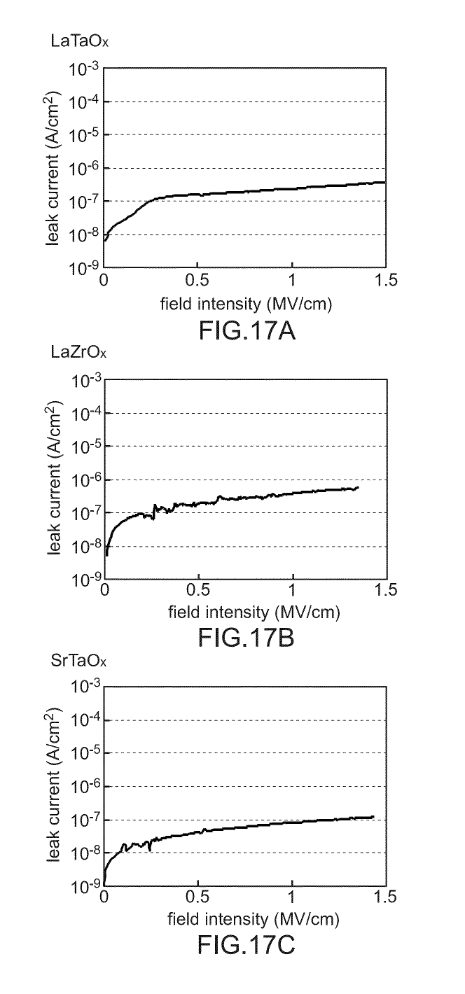

FIG. 17A to FIG. 17C are graphs showing a leak current in a ferroelectric thin film capacitor which uses an LaTaOx layer, an LaZrOx layer or an SrTaOx layer. FIG. 17A shows a data in a case where the LaTaOx layer is used, FIG. 17B shows a data in a case where the LaZrOx layer is used, and FIG. 17C shows a data in a case where an SrTaOx layer is used.

As can be also understood from FIG. 17 A to FIG. 17C, by using the LaZrOx layer or the SrTaOx layer as the Pb diffusion preventing layer, in the same manner as the case where the LaTaOx layer is used as the Pb diffusion preventing layer, it is possible to constitute a ferroelectric thin film capacitor and a ferroelectric gate thin film transistor (and ferroelectric thin film capacitor) where a leak current is small (that is, an OFF current is small).

(3) Although Pt is used as a material for forming the gate electrode layer 22 in the embodiment 1 and lanthanum nickel oxide (LaNiO₃) is used as a material for forming the gate electrode 120 in the embodiments 3, 4, the present invention is not limited to such materials. For example, Au, Ag, Al, Ti, ITO, In₂O₃. Sb—In₂O₃, Nb—TiO₂, ZnO, Al—ZnO, Ga—ZnO, IGZO, RuO₂ and IrO₂ and Nb—STO, SrRuO₂, LaNiO₃, BaPbO₃, LSCO, LSMO, YBCO or a perovskite-type conductive oxide may be used. Further, a pyrochlore-type conductive oxide and an amorphous conductive oxide may be used.

(4) Although the insulating substrate where an STO (SrTiO) layer is formed on the surface of the Si substrate with the SiO₂ layer and the Ti layer interposed therebetween is used as the insulating substrate in the embodiment 3, the present invention is not limited to such an insulating substrate. For example, an SiO₂/Si substrate, an alumina (Al₂O₃) substrate, an STO (SrTiO) substrate or an SRO (SrRuO₃) substrate may be used.

(5) Although the present invention has been explained using the ferroelectric gate thin film transistor where the oxide conductor layer is used as the channel layer in the embodiments 1, 3, 4, the present invention is not limited to such a ferroelectric gate thin film transistor. For example, the present invention is also applicable to a ferroelectric gate thin film transistor where an oxide conductor layer is used for the gate electrode layer. In this case, a Pb diffusion preventing layer formed of a BLT layer, an LaTaOx layer, an LaZrOx layer or an SrTaOx layer is arranged between the PZT layer and the gate insulation layer (oxide conductor layer).

(6) Although the present invention has been explained using the ferroelectric gate thin film transistor and the ferroelectric thin film capacitor in the respective embodiments, the present invention is not limited to such transistor and capacitor. For example, the present invention is applicable to general functional devices which include “the laminated structure having a ferroelectric layer formed of a PZT layer and an oxide conductor layer” (for example, piezoelectric actuator). Also in such a case, a Pb diffusion preventing layer formed of a BLT layer, an LaTaOx layer, an LaZrOx layer or an SrTaOx layer exists between the PZT layer and the oxide conductor layer and hence, the diffusion of Pb atoms into the oxide conductor layer from the PZT layer is prevented whereby various drawbacks which may be caused due to the diffusion of Pb atoms into the oxide conductor layer from the PZT layer can be overcome.

1. A laminated structure comprising:
a ferroelectric layer having the structure where a PZT layer and a Pb diffusion preventing layer formed of a BLT layer, an LaTaOx layer, an LaZrOx layer or an SrTaOx layer are laminated to each other; and
an oxide conductor layer which is arranged on a surface of the ferroelectric layer on a Pb diffusion preventing layer side.

2. The laminated structure according to claim 1, wherein the oxide conductor layer is formed of an ITO layer, an In—O layer or an IGZO layer.

3. The laminated structure according to claim 1, wherein a thickness of the Pb diffusion preventing layer falls within a range of 10 nm to 30 nm.

4. The laminated structure according to claim 1, wherein all of the PZT layer, the oxide conductor layer and the Pb diffusion preventing layer are manufactured using a liquid process.

5. (canceled)

6. (canceled)

7. A ferroelectric gate thin film transistor comprising:
a channel layer;
a gate electrode layer which controls a conductive state of the channel layer; and
a gate insulation layer which is arranged between the channel layer and the gate electrode layer and is formed of a ferroelectric layer, wherein the ferroelectric layer has the structure where a PZT layer and a Pb diffusion preventing layer formed of a BLT layer, an LaTaOx layer, an LaZrOx layer or an SrTaOx layer are laminated to each other,
at least one of the channel layer and the gate electrode layer is formed of an oxide conductor layer, and
the oxide conductor layer is arranged on a surface of the ferroelectric layer on a Pb diffusion preventing layer side.

8. The ferroelectric gate thin film transistor according to claim 7, wherein the oxide conductor layer is formed of an ITO layer, an In—O layer or an IGZO layer.

9. The ferroelectric gate thin film transistor according to claim 7, wherein a thickness of the Pb diffusion preventing layer falls within a range of 10 nm to 30 nm.

10. The ferroelectric gate thin film transistor according to claim 7, wherein all of the PZT layer, the oxide conductor layer and the Pb diffusion preventing layer are manufactured using a liquid process.

11. (canceled)

12. (canceled)

13. The ferroelectric gate thin film transistor according to claim 7, wherein the channel layer is formed of the oxide conductor layer.

14. The ferroelectric gate thin film transistor according to claim 7, wherein the gate electrode layer is formed of the oxide conductor layer.

15. A ferroelectric thin film capacitor comprising:
a first electrode layer;
a second electrode layer, and
a dielectric layer which is arranged between the first electrode layer and the second electrode layer and is formed of a ferroelectric layer, wherein
the ferroelectric layer has the structure where a PZT layer and a Pb diffusion preventing layer formed of a BLT layer, an LaTaOx layer, an LaZrOx layer or an SrTaOx layer are laminated to each other,
at least one of the first electrode layer and the second electrode layer is formed of an oxide conductor layer, and
the oxide conductor layer is arranged on a surface of the ferroelectric layer on a Pb diffusion preventing layer side.

16. The ferroelectric thin film capacitor according to claim 15, wherein the oxide conductor layer is formed of an ITO layer, an In—O layer or an IGZO layer.

17. The ferroelectric thin film capacitor according to claim 15, wherein a thickness of the Pb diffusion preventing layer falls within a range of 10 nm to 30 nm.

18. The ferroelectric thin film capacitor according to claim 15, wherein all of the PZT layer, the oxide conductor layer and the Pb diffusion preventing layer are manufactured using a liquid process.

19. (canceled)

20. (canceled)

21. The ferroelectric thin film capacitor according to claim 15, wherein the first electrode layer and the second electrode layer are formed of the oxide conductor layer respectively, and the ferroelectric layer has the structure where a first Pb diffusion preventing layer arranged on the first electrode layer in a contact manner, the PZT layer and a second Pb diffusion preventing layer arranged on the second electrode layer in a contact manner are laminated to each other.

22. The laminated structure according to claim 1, wherein the Pb diffusion preventing layer is formed of the LaTaOx layer, the LaZrOx layer or the SrTaOx layer.

23. The ferroelectric gate thin film transistor according to claim 7, wherein the Pb diffusion preventing layer is formed of the LaTaOx layer, the LaZrOx layer or the SrTaOx layer.

24. The ferroelectric thin film capacitor according to claim 15, wherein the Pb diffusion preventing layer is formed of the LaTaOx layer, the LaZrOx layer or the SrTaOx layer.
